(19) United States
(12) Patent Application Publication
(10) Pub. No.: US 2014/0375465 A1
(43) Pub. Date: Dec. 25, 2014

(54) BAND WITH CONFORMABLE ELECTRONICS

(71) Applicant: MC10, Inc., Cambridge, MA (US)

(72) Inventors: JACOB FENUCCIO, Boston, MA (US); BRYAN KEEN, Somerville, MA (US); SANJAY GUPTA, Bedford, MA (US); MILAN RAJ, Cambridge, MA (US); NICHOLAS KALITA, Boston, MA (US)

(21) Appl. No.: 14/311,686

(22) Filed: Jun. 23, 2014

Related U.S. Application Data
(60) Provisional application No. 61/838,041, filed on Jun. 21, 2013.

(51) Int. Cl. H05K 5/02; H05K 7/02; G08B 5/36

(52) U.S. Cl. CPC H05K 5/0217; G08B 5/36; H05K 7/02
USPC 340/691.1; 361/679.01

(57) ABSTRACT

An electronic device is disclosed that includes a band, a functional layer disposed over the band, neutral mechanical surface adjusting layers disposed over a portion of the functional layer, and encapsulating layers disposed over the neutral mechanical surface adjusting layers. The band includes a bistable structure having an extended conformation and a curved conformation. The functional layer includes a device island and a stretchable interconnect coupled to the device island at a junction region. At least one of the neutral mechanical surface adjusting layers can have a property that is spatially inhomogeneous relative to a location in the electronic device. The device island and stretchable interconnect are disposed about the band such that the device island and the junction region are disposed at areas of minimal strain of the electronic device in the curved conformation of the bistable structure.

### CROSS-REFERENCE TO RELATED PATENT APPLICATIONS

This application claims priority to U.S. provisional application Ser. No. 61/838,041, filed Jun. 21, 2013, entitled “BAND WITH CONFORMABLE ELECTRONICS,” which is hereby incorporated herein by reference in its entirety.

### BACKGROUND OF THE DISCLOSURE

Existing technology for monitoring movement may require either an expensive 3-D motion capture/video analysis system, or for an athlete to wear bulky devices in a laboratory that can impede on performance. Some of the bulkier systems can be external (video capture) devices. This technology is not suitable for real-time or on-field monitoring. Due to the restrictive nature of placing rigid electronics on an athlete, there do not appear to be any low-form factor electronic products on the market.

### SUMMARY OF THE DISCLOSURE

In view of the foregoing, systems, apparatus and methods are provided for quantifying a metric of a performance and/or physiological data of a user, and/or an environmental condition, using measurement data obtained using an example electronic device. In some implementations, the system can be disposed into conformal electronics that can be coupled to or disposed on a portion of the user. The system can include a storage module to allow for data to be reviewed and analyzed. In some implementations, the system can also include an indicator. In some implementations, the indicator can be used to display real time analysis of impacts made by the system.

The example systems, methods, and apparatus according to the principles described herein provide better performance for looking at body motion than large and bulky devices.

In an example, the portion of the user can be a head, a foot, a chest, an abdomen, a shoulder, a torso, a thigh, or an arm.

An example system, method and apparatus described herein provides an electronic device that includes a band, a functional layer disposed over a surface of the band, one or more neutral mechanical surface adjusting layers disposed over at least a portion of the functional layer, and one or more encapsulating layers disposed over the one or more neutral mechanical surface adjusting layers. The band includes a bistable structure, the bistable structure having an extended conformation and a curved conformation. The functional layer includes at least one device island and at least one stretchable interconnect coupled to the at least one device island at a junction region. The one or more neutral mechanical surface adjusting layers have a property that is spatially inhomogeneous relative to a location in the electronic device. The at least one device island and at least one stretchable interconnect are disposed about the band such that the at least one device island and the junction region are disposed at areas of minimal strain of the electronic device in the curved conformation of the bistable structure.

In an example, the spatially inhomogeneous property, the at least one stretchable interconnect, and the one or more encapsulating layers position a spatially varying neutral mechanical surface that is coincident with or proximate to the functional layer.

The one or more encapsulating layers can have a thickness that varies selectively in a lateral direction.

In an example, the band can also include a polymer, a semiconductor material, a ceramic, a metal, a fabric, a vinyl material, leather, latex, spandex, or paper.

The at least one stretchable interconnect can include a pop-up interconnect, a curved interconnect, a serpentine interconnect, a wavy interconnect, a meander-shaped interconnect, a zig-zag interconnect, a boustrophedonic interconnect, a rippled interconnect, a buckled interconnect, or a helical interconnect.

In an example, the at least one stretchable interconnect can be an electrically conductive stretchable interconnect or an electrically non-conductive stretchable interconnect.

In an example, the at least one functional layer can include an optical device, a mechanical device, a microelectromechanical device, a thermal device, a chemical sensor, an accelerometer, a flow rate sensor, or any combination thereof.

In an example, one or more of the at least one device island can include a device component selected from the group consisting of a photodiode, a light-emitting diode, a thin-film transistor, a memory, a electrocardiogram electrode, an electromyogram electrode, an integrated circuit, a contact pad, a circuit element, a control element, a microprocessor, a transducer, a biological sensor, a chemical sensor, a temperature sensor, a light sensor, an electromagnetic radiation sensor, a solar cell, a photovoltaic array, a piezoelectric sensor, an environmental sensor, or any combination thereof.

The functional layer can include at least one light-emitting device, and at least one sensor component, where the at least one sensor component measures at least one parameter indicative of at least one of a physiological measure of a subject and an environmental condition, and where a visual appearance of the at least one light-emitting device changes based on a magnitude of the at least one parameter.

In this example, the physiological measure can be at least one of a skin temperature, a body temperature, a heart rate, a hydration state, a quantify of sweat, a blood pressure, a cardiac electricity, a muscle electricity, a stomach electricity, a skin electricity, a nerve electricity, UV exposure, and a hormone level.

In this example, the physiological measure can be a quantity of at least one of a drug, a pharmaceutical, or a biologic, in a portion of a tissue of the subject, sweat from the subject, and/or body fluid from the subject.

In this example, the environmental condition can be at least one of a humidity, an atmospheric temperature, an amount of chlorofluorocarbon, an amount of volatile organic compound, a UV level, and an atmospheric pressure.

The bistable structure comprises a tape spring steel or a carbon spring steel.

In an aspect, the electronic device can further include at least one triggering mechanism. The at least one triggering mechanism can be coupled to the band such that at least one device component of the at least one device island is activated when the bistable structure is in the extended conformation and such that the at least one device component of the at least one device island is deactivated when the bistable structure is in the curved conformation.

In this example, the at least one device component can be an accelerometer, a photodiode, a light-emitting diode, a microprocessor, a transducer, a biological sensor, a chemical sensor, a temperature sensor, a light sensor, an electromagnetic radiation sensor, a piezoelectric sensor, an environmental sensor, or any combination thereof.

In this example, the at least one triggering mechanism can include at least one of contact pads, a mechanical snap switch, a dome switch, and magnets.

In an example, the electronic device can further include at least one wireless component that has a linear configuration when the bistable structure is in the extended conformation and has a charging coil configuration when the bistable structure is in the curved conformation.

An example system, method and apparatus described herein provides an electronic device that includes a band, an isolation layer disposed over a portion of the band, a functional layer disposed over a surface of the band, one or more neutral mechanical surface adjusting layers disposed over at least a portion of the functional layer, and one or more encapsulating layers disposed over the one or more neutral mechanical surface adjusting layers. The band includes a plurality of bistable structures, each having an extended conformation and a curved conformation. At least a portion of the isolation layer is disposed over at least one bistable structure of the plurality of bistable structures. The functional layer includes at least one device island and at least one stretchable interconnect coupled to the at least one device island at a junction region. At least a portion of the device island and the junction region are in physical communication with the isolation layer. At least a portion of the stretchable interconnect is not in physical communication with the isolation layer. The one or more neutral mechanical surface adjusting layers have a property that is spatially inhomogeneous relative to a location in the electronic device. The at least one device island and at least one stretchable interconnect are disposed about the band such that the at least one device island and the junction region are disposed at areas of minimal strain of the electronic device in the curved conformation of at least one of the plurality of bistable structures.

In an example, the spatially inhomogeneous property, the at least one stretchable interconnect, and the one or more encapsulating layers position a spatially varying neutral mechanical surface that is coincident with or proximate to the functional layer.

The band can also include a polymer, a semiconductor material, a ceramic, a metal, a fabric, a vinyl material, leather, latex, spandex, or paper.

In an example, the at least one stretchable interconnect can include a pop-up interconnect, a curved interconnect, a serpentine interconnect, a wavy interconnect, a meander-shaped interconnect, a zig-zag interconnect, a boustrophedonic interconnect, a rippled interconnect, a buckled interconnect, or a helical interconnect.

In an example, the at least one stretchable interconnect can be formed as an electrically conductive stretchable interconnect or an electrically non-conductive stretchable interconnect.

The at least one functional layer can include an optical device, a mechanical device, a microelectromechanical device, a thermal device, a chemical sensor, an accelerometer, a flow rate sensor, or any combination thereof.

In an example, one or more of the at least one device island can include a device component selected from the group consisting of a photodiode, a light-emitting diode, a thin-film transistor, a memory, a electrocardiogram electrode, an electromyogram electrode, an integrated circuit, a contact pad, a circuit element, a control element, a microprocessor, a transducer, a biological sensor, a chemical sensor, a temperature sensor, a light sensor, an electromagnetic radiation sensor, a solar cell, a photovoltaic array, a piezoelectric sensor, an environmental sensor, or any combination thereof.

In an example, the functional layer includes at least one light-emitting device and at least one sensor component. The at least one sensor component can be used to measure at least one parameter indicative of at least one of a physiological measure of a subject and an environmental condition. A visual appearance of the at least one light-emitting device changes based on a magnitude of the at least one parameter.

In an aspect, the physiological measure is at least one of a skin temperature, a body temperature, a heart rate, a hydration state, a quantify of sweat, a blood pressure, a cardiac electricity, a muscle electricity, a stomach electricity, a skin electricity, a nerve electricity, UV exposure, and a hormone level.

In an aspect, the physiological measure is a quantity of at least one of a drug, a pharmaceutical, or a biologic, in a portion of a tissue of the subject, sweat from the subject, and/or body fluid from the subject.

In an aspect, the environmental condition is at least one of a humidity, an atmospheric temperature, an amount of chlorofluorocarbon, an amount of volatile organic compound, a UV level, and an atmospheric pressure.

In an example, at least one bistable structure of the plurality of bistable structures includes a tape spring steel or a carbon spring steel.

In an example, the electronic device can further include at least one wireless component that has a linear configuration when at least one bistable structure of the plurality of bistable structures is in the extended conformation and has a charging coil configuration when at least one bistable structure of the plurality of bistable structures is in the curved conformation

Other features and advantages of the invention will be apparent from and encompassed by the following detailed description and claims.

### BRIEF DESCRIPTION OF THE DRAWINGS

The skilled artisan will understand that the figures, described herein, are for illustration purposes only. It is to be understood that in some instances various aspects of the described implementations may be shown exaggerated or enlarged to facilitate an understanding of the described implementations. In the drawings, like reference characters generally refer to like features, functionally similar and/or structurally similar elements throughout the various drawings. The drawings are not necessarily to scale, emphasis instead being placed upon illustrating the principles of the teachings. The drawings are not intended to limit the scope of the present teachings in any way. The system, apparatus and method may be better understood from the following illustrative description with reference to the following drawings in which:

FIG. 1 shows an example electronic device, according to the principles described herein.

FIG. 2 shows an example electronic device, according to the principles described herein.

FIG. 3 shows an example electronic device, according to the principles described herein.

FIG. 4 shows example of the cross-section of a portion of an electronic device, according to the principles described herein.

FIG. 5 shows an example of the cross-section of a portion an electronic device, according to the principles described herein.

FIG. 6 shows an example electronic device, according to the principles described herein.

FIG. 7 shows an example electronic device, according to the principles described herein.

FIGS. 8 and 9 show top views of a section of example electronic device, according to the principles described herein.

FIG. 10 shows an example electronic device, according to the principles described herein.

FIGS. 11A-11D show block diagrams of example electronic devices, according to the principles herein.

FIGS. 12A-12C show block diagrams of example electronic devices, according to the principles herein.

FIG. 13 shows a flow chart of an example method, according to the principles herein.

FIG. 14 shows a general architecture for a computer system, according to the principles herein.

FIG. 15A shows components of an example electronic device, according to the principles herein.

FIG. 15B shows the example electronic device, according to the principles herein.

FIG. 16 shows a non-limiting example of an electronic device formed as a band, according to the principles herein.

FIG. 17 shows a non-limiting example of an electronic device formed as a band, according to the principles herein.

FIG. 18 shows components of an example electronic device, according to the principles herein.

FIG. 19 shows an example electronic device, according to the principles herein.

FIGS. 20-25 show differing views and conformations of an example electronic device, according to the principles described herein.

FIG. 26 shows the cross-section of an example electronic device, according to the principles herein.

### DETAILED DESCRIPTION

It should be appreciated that all combinations of the concepts discussed in greater detail below (provided such concepts are not mutually inconsistent) are contemplated as being part of the inventive subject matter disclosed herein. It also should be appreciated that terminology explicitly employed herein that also may appear in any disclosure incorporated by reference should be accorded a meaning most consistent with the particular concepts disclosed herein.

Following below are more detailed descriptions of various concepts related to, and embodiments of, inventive methods, apparatus and systems for quantifying a metric of a performance and/or physiological data of a user, and/or an environmental condition, using measurement data obtained using an example electronic device. The example electronic devices can include at least one bistable structure. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

As used herein, the term “includes” means includes but is not limited to, the term “including” means including but not limited to. The term “based on” means based at least in part on.

With respect to substrates or other surfaces described herein in connection with various examples of the principles herein, any references to “top” surface and “bottom” surface are used primarily to indicate relative position, alignment and/or orientation of various elements/components with respect to the substrate and each other, and these terms do not necessarily indicate any particular frame of reference (e.g., a gravitational frame of reference). Thus, reference to a “bottom” of a substrate or a layer does not necessarily require that the indicated surface or layer be facing a ground surface. Similarly, terms such as “over,” “under,” “above,” “beneath” and the like do not necessarily indicate any particular frame of reference, such as a gravitational frame of reference, but rather are used primarily to indicate relative position, alignment and/or orientation of various elements/components with respect to the substrate (or other surface) and each other. The terms “disposed on” and “disposed over” encompass the meaning of “embedded in,” including “partially embedded in.” In addition, reference to feature A being “disposed on,” “disposed between,” or “disposed over” feature B encompasses examples where feature A is in contact with feature B, as well as examples where other layers and/or other components are positioned between feature A and feature B.

Example systems, methods and apparatus are described for quantifying the performance of a user using an example electronic device mounted to a portion of the user. The performance of the user can be quantified using an electronic device according to the principles of any example herein.

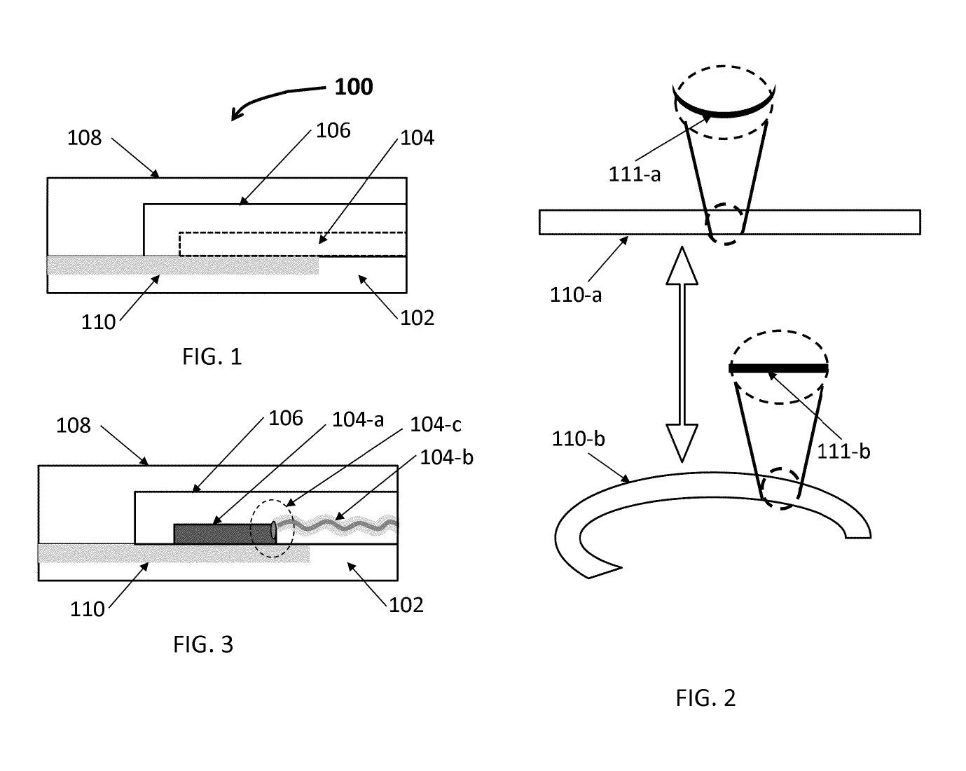

FIG. 1 shows an example electronic device 100 according to the principles described herein. The example electronic device includes a substrate 102, a functional layer 104 disposed over the surface of the substrate 102, one or more neutral mechanical surface adjusting layers 106 disposed over at least a portion of the functional layer, and one or more encapsulating layers 108 disposed over at least a portion of the one or more neutral mechanical surface adjusting layers. The substrate 102 can be a one-dimensional structure (e.g., a band), or can be two-dimensional structure (e.g., a sheet). The substrate 102 includes at least one bistable structure 110.

As shown in FIG. 2, the bistable structure 110 is configured to have two stable conformations, an extended conformation 110-a, and a curved conformation 110-b. The curved conformations 110-b can be a coiled conformations. As shown in FIG. 2, the bistable structure 110 can have a curved lateral cross-section 111-a when in the extended conformations 110-a, and a somewhat flattened lateral cross-section 111-b when in the curved conformation 110-b. The bistable structure 110 can be formed from a bi-stable metal, such as but not limited to a type of tape spring steel or carbon spring steel. In the extended conformation 110-a, the bistable structure 110 has stored potential energy that is released when the bistable structure 110 is deformed. On deformation, the bistable structure 110 curves into the curved conformation 110-b.

The deformation behavior of the bistable structure 110 can be characterized by parameters such as, but not limited to, the speed of the deformation (which depends on the strength of metal), length and thickness of metal, shape of the cross section, defects within the metal, orientation of cross-section (whether any cross sectional curve is facing up or down, presence of the other materials and/or components layered on the bistable structure. In an example, two or more bistable structures may be layered together to provide a curved conformation with less curvature. As a non-limiting example, the bistable structure 110 can be formed as a beryllium-copper tape structure that has a curved cross-section. When the cross section is deformed, the bistable structure destabilizes from the extended conformation and curves to form the curved conformation (also referred to as collapsing). The curved cross-section in the extended conformation allows the bistable structure to remain straight. The combination of features gives the bistable structure 110 its bi-stable characteristics. The curving of the bistable structure 110 into the curved conformation causes at least a portion of portion of the substrate 102 of the electronic device to curve.

As shown in FIG. 3, the functional layer 104 can include at least one device island 104-a, at least one stretchable interconnect 104-b coupled to the at least one device island 104-a at a junction region 104-c.

The layered structure of the electronic device is configured, and the device island(s) and stretchable interconnect(s) are disposed about the band, such that at least a portion of the device island and the junction region are disposed at areas of minimal strain of the electronic device when the bistable structure is in the curved conformation.

The one or more neutral mechanical surface adjusting layers are configured to have a property that is spatially inhomogeneous relative to a location in the electronic device. The spatially inhomogeneous layers and patterning of the one or more neutral mechanical surface adjusting layers facilitates the positioning of a neutral mechanical surface (NMS) as desired. The spatial inhomogeneity property includes, but is not limited to, varying the Young's modulus across the curvature of the bistable structure versus other portions of the electronic device, varying layer thickness in the region of the bistable structure versus other portions of the electronic device, the selective positioning the device islands relative to the curvature of the bistable structure based on the dimensions and patterning of the electronic components disposed on the device islands, the positioning of junction regions based on the degree of susceptibility of the junction region to fracture, and the stretchability and compressibility of the stretchable interconnects. In an example, the Young's modulus can be varied by modifying the layer rigidity in selective regions, e.g., through UV exposure.

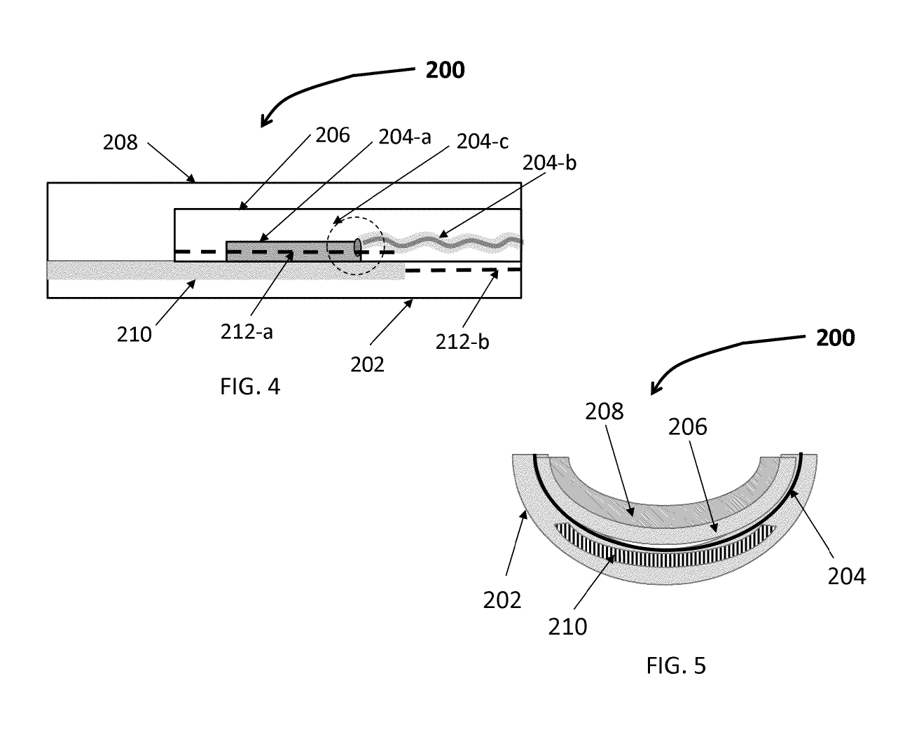

FIG. 4 shows example of the cross-section of a portion of an electronic device 200 showing the positioning of a spatially-varying NMS. The electronic device 200 includes a substrate 202, a functional layer 204 disposed over the surface of the substrate 202, one or more neutral mechanical surface adjusting layers 206 disposed over at least a portion of the functional layer, and one or more encapsulating layers 208 disposed over at least a portion of the neutral mechanical surface adjusting layer(s) 206. The substrate 202, one or more neutral mechanical surface adjusting layers 206, and one or more encapsulating layers 208, are configured as described herein such that a spatially-varying NMS (212-a and 212-b) is disposed proximate to or coincident with portions of the functional layer 204. For example, NMS 212-a is positioned coincident with portions of the device island 204-a and junction region 204-c in the region of the functional layer proximate to the bistable structure 210, but NMS 212-b is disposed at a different relative position in the electronic device 200 in the area of functional layer 204 that includes the stretchable interconnect 204-b.

FIG. 5 shows an example of the cross-section of a portion of the electronic device 200 of FIG. 4 with the device deformed to a curved conformation. In this example, a bistable structure 210 is disposed in a portion of the substrate 202 such that the curved conformation of the bistable structure 210 causes the deformation (i.e., curvature) of the portion of the electronic device 200. The example electronic structure is configured such that the spatially-varying NMS remains positioned coincident with or proximate to portions of the functional layer, even with the differing conformations of the substrate 202 and bistable structure 210 (i.e., whether extended or curved).

In any example electronic device herein, the encapsulating layer(s) can be configured to have a thickness that varies selectively in a lateral direction of the electronic device.

In an example, the spatially inhomogeneous property, the at least one stretchable interconnect, and the one or more encapsulating layers position a spatially varying NMS that is coincident with or proximate to the functional layer.

In an example, the one or more NMS adjusting layers can be selectively positioned such that the NMS is positioned proximate to or coincident with portions of the functional layer. For example, portions of the device island, the junction region, and/or other portions of the stretchable interconnect, can be formed from materials or include electronic components that are sensitive to an applied strain. In the presence of an applied strain above a threshold value, the materials or electronic components may fracture or simply cease functioning.

The kinetics of the curving motion of the bistable structure from the extended conformation to the curved conformation can exert a force sufficient to cause some fracture or malfunctioning of the strain-sensitive portions of the functional layer. In addition, the change of the lateral cross-section of the bistable structure, from a curved lateral cross-section (in the extended conformation) to a flattened lateral cross-section (in the curved conformation), also changes the nature of the applied forces to the functional layer. According to the principles described herein, the strain-sensitive portions of the functional layer are disposed at selective regions of minimal strain of the overall electronic device, including in the regions with the bistable structure(s). The positioning, composition, and number of neutral mechanical surface adjusting layers relative to the functional layer is targeted to position the NMS proximate to or coincident with portions of the functional layer whether the bistable structure is in the extended conformation or in the curved conformation. The geometry of the device islands and the degree of stretchability and compressibility achievable by the stretchable interconnect also factors into determining the positioning of the NMS.

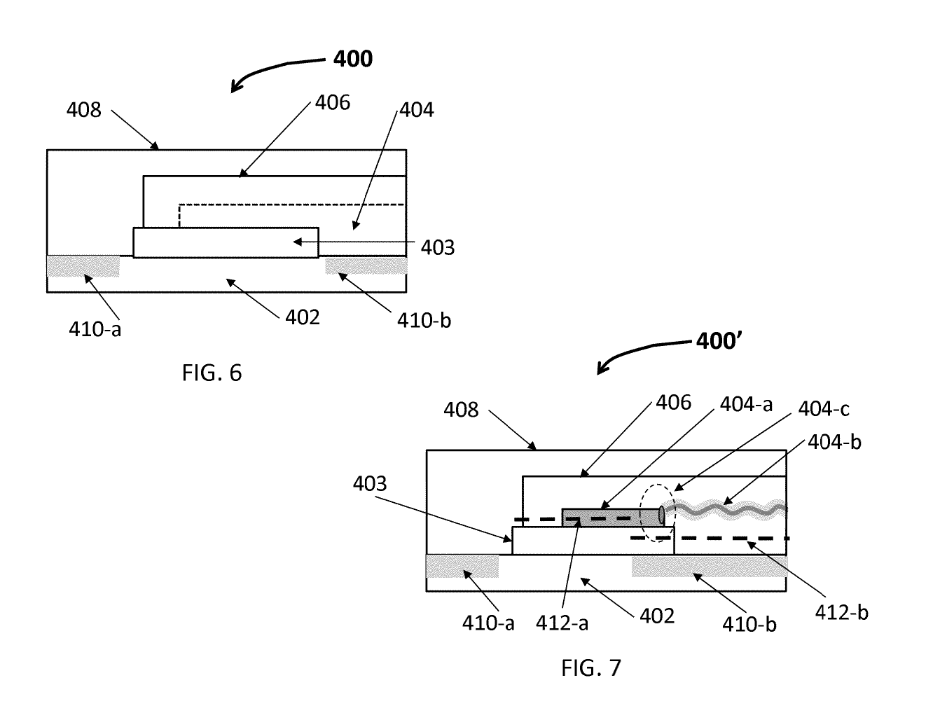

FIG. 6 shows another example electronic device 400 according to the principles described herein. The example electronic device includes a substrate 402, an isolation layer 403 disposed over a portion of the substrate 402, a functional layer 404 disposed over the surface of the substrate 402, one or more neutral mechanical surface adjusting layers 406 disposed over at least a portion of the functional layer, and one or more encapsulating layers 408 disposed over at least a portion of the one or more neutral mechanical surface adjusting layers. The substrate 402 can be a one-dimensional structure (e.g., a band), or can be two-dimensional structure (e.g., a sheet). The substrate 402 includes bistable structures 410-a and 410-b. The isolation layer 403 is disposed over at least one of the bistable structures.

As shown in the example electronic device 400′ of FIG. 7, the functional layer 404 can include at least one device island 404-a, at least one stretchable interconnect 404-b coupled to the at least one device island 404-a at a junction region 404-c. At least a portion of the device island 404-a and the junction region 404-c is in physical communication with the isolation layer 403.

While the example electronic device 200 of FIG. 4 shows the bistable structure 210 can be positioned beneath portions of a device island 204-a and junction region 204-c, the example electronic device 400′ of FIG. 7 shows that bistable structure 410-b also may be positioned beneath portions of a stretchable interconnect 404-b and junction region 404-c.

The layered structure of the electronic device is configured, and the device island(s) and stretchable interconnect(s) are disposed about the substrate (such as but not limited to a band), such that at least a portion of the device island and the junction region are disposed at areas of minimal strain of the electronic device in the curved conformation of at least one of the plurality of bistable structures. The one or more neutral mechanical surface adjusting layers are configured to have a property that is spatially inhomogeneous relative to a location in the electronic device.

In an example, the spatially inhomogeneous property, the at least one stretchable interconnect, and the one or more encapsulating layers position a spatially varying neutral mechanical surface that is coincident with or proximate to the functional layer.

For example, as shown in the example of FIG. 7, a NMS 412-a can be positioned coincident with portions of the device island 404-a and junction region 404-c in the region of the functional layer proximate to isolation layer 403 and the bistable structure(s) 410-a and 410-b, while NMS 412-b is disposed at a different relative position in the electronic device 400′ in the area of the functional layer that includes the stretchable interconnect 404-b. In this example, bistable structures 410-a and 410-b are disposed in portions of the substrate 402 such that the curved conformation of at least one of the bistable structures 410-a and 410-b causes the deformation (i.e., curvature) of a portion of the electronic device 400′. The example electronic structure is configured such that the spatially-varying NMS remains positioned coincident with or proximate to portions of the functional layer, even with the differing conformations of the substrate 402 and at least one of the bistable structures 410-a and 410-b (i.e., whether extended or curved).

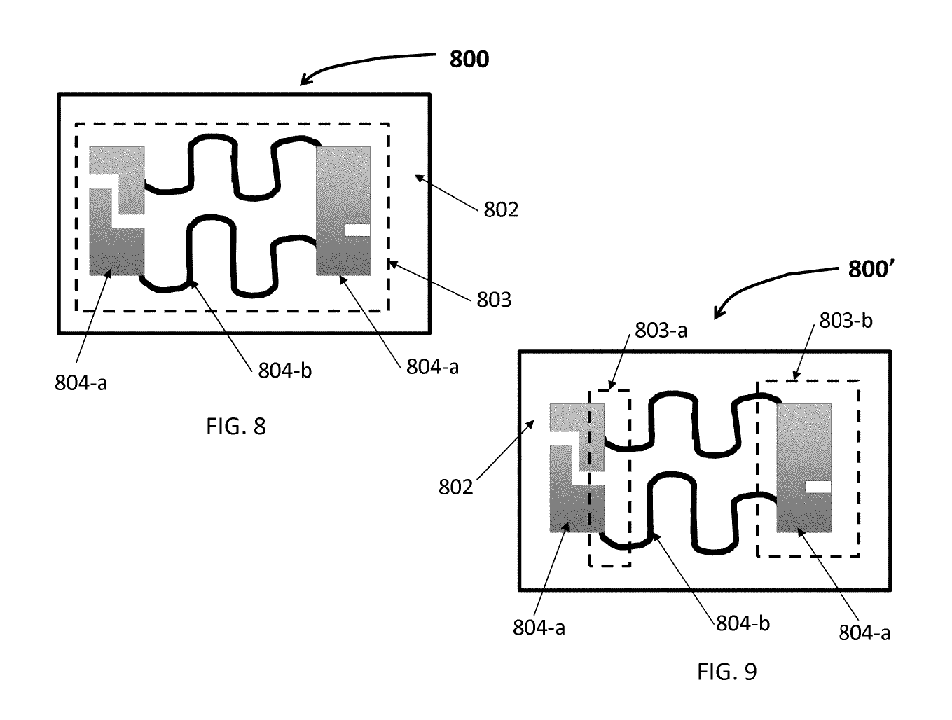

FIGS. 8 and 9 show top views of a section of example electronic devices 800 and 800′. The example electronic device 800 includes a substrate 802, an isolation layer 803 disposed over the substrate 802, device islands 804-a, and stretchable interconnects 804-b that couple the device islands 804-a to each other. In this non-limiting example, device islands 804-a and stretchable interconnects 804-b are disposed over portions of the isolation layer 803. The example electronic device 800′ includes a substrate 802, isolation layers 803-a and 803-b disposed over the substrate 802, device islands 804-a, and stretchable interconnects 804-b that couple the device islands 804-a to each other. This non-limiting example shows differing types of isolation layers that can be used to position the NMS selectively in differing regions of the electronic device 800′. Isolation layer 803-a is disposed below the junction region between a device island 804-a and a stretchable interconnect 804-b, while Isolation layer 803-b is disposed below an entire device island 804-a and the junction region between the device island 804-a and a stretchable interconnect 804-b.

In any of the example electronic devices according to the principles described herein, including the example electronic device shown in any of FIGS. 1-9, the substrate can include a polymer, a semiconductor material, a ceramic, a metal, a fabric, a vinyl material, leather, latex, spandex, paper, or any combination of these materials.

In any of the example devices according to the principles described herein, including the example electronic device shown in any of FIGS. 1-9, the at least one stretchable interconnect includes a pop-up interconnect, a curved interconnect, a serpentine interconnect, a wavy interconnect, a meander-shaped interconnect, a zig-zag interconnect, a boustrophedonic interconnect, a rippled interconnect, a buckled interconnect, a helical interconnect, or any other conformation of interconnect that facilitates stretchability.

In any example herein, the stretchable interconnect can be an electrically conductive stretchable interconnect or an electrically non-conductive stretchable interconnect. The non-conductive portions of the stretchable interconnects can be used for mechanical stability (e.g., to maintain form factor with stretching or other deformation of the electronic device).

According to the principles described herein, the functional layer of an example electronic device can include an optical device, a mechanical device, a microelectromechanical device, a thermal device, a chemical sensor, an accelerometer, a flow rate sensor, or any combination thereof.

For example, a device island of any of the example electronic devices according to the principles described herein can include at least one device component such as, but not limited to, a photodiode, a light-emitting diode, a thin-film transistor, a memory, a electrocardiogram electrode, an electromyogram electrode, an integrated circuit, a contact pad, a circuit element, a control element, a microprocessor, a transducer, a biological sensor, a chemical sensor, a temperature sensor, a light sensor, an electromagnetic radiation sensor, a solar cell, a photovoltaic array, a piezoelectric sensor, an environmental sensor, or any combination thereof.

In an example implementation, the functional layer of an example device can include at least one light-emitting device and at least one sensor component. The at least one sensor component can be configured to measure a parameter that indicates a physiological measurement of a subject, or an environmental condition. The example electronic device can be configured such that the visual appearance of the at least one light-emitting device changes based on a magnitude of the parameter measured.

As non-limiting examples, the physiological measurement of the subject can be a measure of skin temperature, hydration, quantify of sweat, body temperature, heart rate, blood pressure, cardiac electricity, muscle electricity, stomach electricity, skin electricity, nerve electricity, UV exposure, and/or hormone level.

In an example, the physiological measurement of the subject can be a measure of the quantity of (including determining the presence or absence of) a drug, a pharmaceutical substance, a biologic or other non-native chemical substance in a portion of the tissue of the subject, sweat from the subject, and/or body fluid from the subject.

As non-limiting examples, the environmental condition can be a measure of humidity, atmospheric temperature, an amount of chlorofluorocarbon, an amount of volatile organic compound, UV level, and an atmospheric pressure.

In an example implementation, the electronic device can be configured with a triggering mechanism that is coupled to the conformation of the substrate, including the conformation of at least one of the bistable structure(s) in the substrate. For example, the triggering mechanism can cause one or more device components of a device island to be activated when at least one of the bistable structure(s) is in the extended conformation and to be de-activated when at least one of the bistable structure(s) is in the curved conformation.

In an example where the substrate is in the form of a band, the electronic device can be configured such that the triggering mechanism activates one or more of the device component(s) of a device island when the band is in an extended conformation, and de-activates one or more of the device component(s) of the device island when the band is in a curved conformation.

As non-limiting examples, the triggering mechanism can cause activation and/or deactivation of device components such as an accelerometer, a photodiode, a light-emitting diode, a microprocessor, a transducer, a biological sensor, a chemical sensor, a temperature sensor, a light sensor, an electromagnetic radiation sensor, a piezoelectric sensor, an environmental sensor, or any combination thereof.

In various example implementations, the triggering mechanism can be based on contact pads, a mechanical snap switch, a dome switch, magnets, or any other mechanism in the art.

In an example implementation, the electronic device can further include at least one wireless component that is coupled to the conformation of the substrate, including the conformation of at least one of the bistable structure(s) in the substrate. For example, the wireless component can have a linear configuration when the substrate (including the bistable structure(s)) is in the extended conformation and has a charging coil configuration when the substrate (including the bistable structure(s)) is in the curved conformation.

In an example where the substrate is in the form of a band, the electronic device can be configured such that the wireless component has a linear configuration when the band is in the extended conformation, and has a charging coil configuration when the band is in the curved conformation.

An example system, method and apparatus according to the principles described herein includes the components described in connection with any of the example electronic devices and at least one other component.

In an example, the at least one other component can be, but is not limited to, at least one memory for storing processor executable instructions, and a processing unit for accessing the at least one memory and executing the processor executable instructions. The processor executable instructions include a communication module to receive data indicative of measurements of a sensor component of the example electronic device. The example sensor component can be disposed on one or more of the example device islands.

In an example, the sensor component can be configured to measure data representative of an acceleration proximate to the portion of the user to which the example electronic device is coupled, including but not limited to the wrist, arm, neck, thigh, knee, torso, calf, head, foot, and/or ankle. The sensor measurement data can include data indicative of a degree of the conformal contact of the electronic device with a portion of the user. The processor executable instructions also include an analyzer to quantify a parameter indicative of an imparted energy to the user, based at least in part on the sensor component measurement and data indicative of the degree of the conformal contact. A comparison of the parameter to a preset performance threshold value provides an indication of the physical performance of the user.

In an example, the imparted energy can be computed as an area under a curve from acceleration measurement data, such as but not limited to a force versus distance curve. In some examples, the imparted energy can be computed based on the integral of a time variation of a linear motion and/or acceleration in motion of the body part. Accordingly, the imparted energy calculation can take into account the magnitude and duration of motion of the body part.

In another example, the sensor component can be configured to measure data representative of a sensor measurement proximate to the portion of the user to which the example electronic device is coupled, including but not limited to the wrist, arm, neck, thigh, knee, torso, calf, head, foot, and/or ankle Non-limiting examples of such sensor measurements include, but are not limited to, a muscle activation measurement, a heart rate measurement, an electrical activity measurement, a temperature measurement, a hydration level measurement, a neural activity measurement, a conductance measurement, an environmental measurement, and/or a pressure measurement. In various examples, the example electronic device can be configured to perform any combination of two or more different types of sensor measurements. The sensor measurement data can include data indicative of a degree of the conformal contact of the electronic device with a portion of the user. The processor executable instructions also include an analyzer to quantify a parameter indicative of physiological state (including a state of health and/or fitness) of the user and/or an environmental condition, based at least in part on the sensor component measurement and data indicative of the degree of the conformal contact. In an example, a comparison of a parameter related to a physiological measurement to a preset physiological state threshold value provides an indication of the physiological state (including a state of health and/or fitness) of the user. As non-limiting examples, the preset physiological state threshold value can be a target heart rate, a minimum acceptable heart rate for an activity, a muscle activation level, an electrical activity, an target skin temperature measurement, a target hydration level, a desired neural activity, and/or an amount of conductance. In an example, a comparison of a parameter related to an environmental measurement to a desired environmental state threshold value provides an indication of the environmental condition.

In a non-limiting example, the preset performance threshold value and/or the preset physiological state threshold value can be determined based on previous sensor measurement data from the user, and/or representative sensor measurement data from a plurality of other individuals (with pertinent consent). For example, the preset physiological state threshold value can be determined based on an averaged sensor measurement data from a plurality of other individuals, median sensor measurement data from the plurality of other individuals, or other statistical measure of sensor measurement data from the plurality of other individuals.

According to the principles described herein, the measurement data and/or the indication of the performance and/or the physiological state of the user, and/or the environmental condition, may be displayed using a display or other indicator of the system, stored to a memory of the system, and/or transmitted to an external computing device and/or the cloud. In an example, the system may include a data receiver that is configured to receive data transmitted by the sensor component to provide the measurement data. In example, the data receiver can be a component of a device that is integral with the example electronic device.

In an example, the system can include at least one indicator disposed on a portion of the example electronic device, to display the indication of the performance and/or the physiological state of the user. The indicator may be a liquid crystal display, an electrophoretic display, or an indicator light. The example system can be configured such that indicator light appears different if the indication of the performance and/or the physiological state of the user, and/or the environmental condition, is below the respective threshold value than if the indication meets or exceeds the respective threshold value.

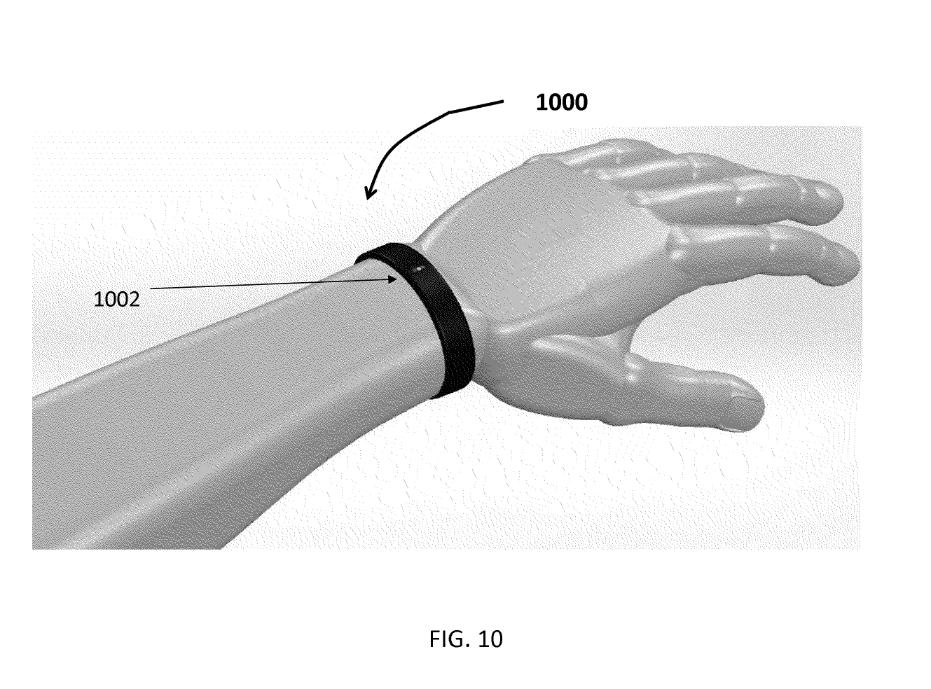

FIG. 10 shows a non-limiting example implementation of an electronic device 1000 formed as a band and disposed about a wrist of a user. The example electronic device includes indicator light 1002 that can be used to indicate whether the performance and/or the physiological state of the user, and/or the environmental condition, is below the respective threshold value, or meets or exceeds the respective threshold value, according to the principles described herein.

Non-limiting examples of a computing device applicable to any of the example systems, apparatus or methods according to the principles herein include a smartphone (such as but not limited to an Iphone®, an Android™ phone, or a Blackberry®), a tablet computer, a laptop, a slate computer, an electronic gaming system (such as but not limited to an XBOX®, a Playstation®, or a Wii®), an electronic reader (an e-reader), and/or other electronic reader or hand-held or wearable computing device.

For any of the example systems, methods, and apparatus herein, the user may be a human subject or a non-human animal (such as but not limited to a dog, a cat, a bird, a horse, or a camel). In a non-human animal, the example electronic device may be disposed on or otherwise coupled to the neck, thigh, head, and/or paw or hoof, as applicable).

The example systems, methods, and apparatus described herein use an analysis of data indicative of body motion and/or a physiological measure, as non-limiting examples, for such applications as physical training and/or clinical purposes.

Example systems, methods, and apparatus according to the principles described herein provide a thin and conformal electronic measurement system capable of measuring body motion or body part for a variety of applications, including rehabilitation, physical therapy, athletic training, and athlete monitoring. Additionally, the example systems, methods, and apparatus can be used for athlete assessment, performance monitoring, training, and performance improvement.

An example electronic device herein that can be used for motion detection can include an accelerometer (such as but not limited to a 3-axis accelerometer). The example device may include a 3-axis gyroscope. The example electronic device can be disposed on a body part, and data collected based on the motion of the body part is analyzed, and the energy under the motion vs. time curve can be determined as an indicator of energy or impulse of a motion.

The example electronic device can be about 2 mm or less in thickness. The example patch can be attached adhesively to the body part similar to that of a band-aid or other bandage.

As a non-limiting example, the device architecture can include one or more sensors, power & power circuitry, wireless communication, and a microprocessor. These example devices can implement a variety of techniques to thin, embed and interconnect these die or package-based components.

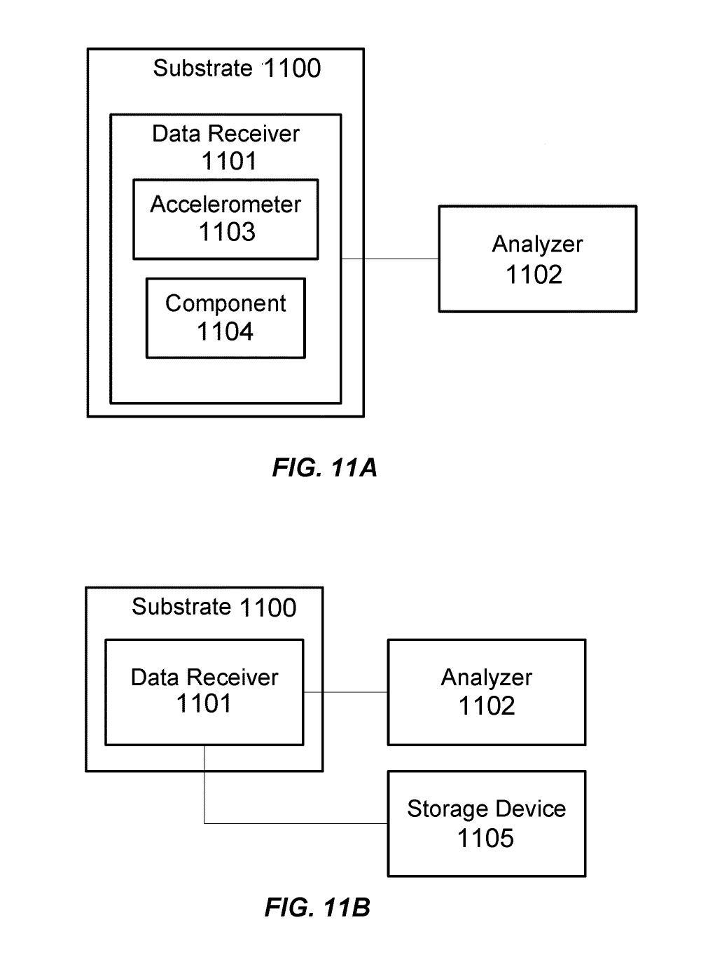

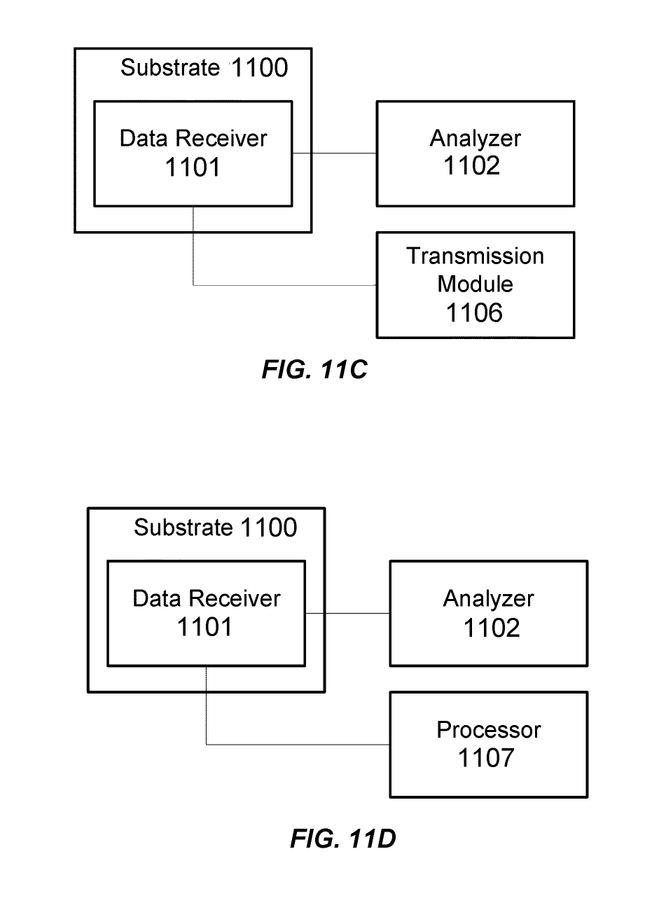

FIGS. 11A-11D show non-limiting examples of possible electronic device configurations. The example electronic device of FIG. 11A includes a data receiver 1101 disposed on a device island on substrate 1100. The data receiver 1101 can be configured to conform to a portion of the portion of the subject to which it and the substrate are coupled. The data receiver 1101 can include one or more of any sensor component according to the principles of any of the examples and/or figures described herein. In this example, data receiver 1101 includes at least one accelerometer 1103 (such as but not limited to a triaxial accelerometer) and at least one other component 1104. As a non-limiting example, the at least one other component 1104 can be a gyroscope, hydration sensor, temperature sensor, an electromyography (EMG) component, a battery (including a rechargeable battery, a transmitter, a transceiver, an amplifier, a processing unit, a charger regulator for a battery, a radio-frequency component, a memory, and an analog sensing block, electrodes, a flash memory, a communication component (such as but not limited to Bluetooth® Low-Energy (BTLE) radio) and/or other sensor component.

The at least one accelerometer 1103 can be used to measure data indicative of a motion of a portion of the user. The example electronic device of FIG. 11A also includes an analyzer 1102. The analyzer 1102 can be configured to quantify the data indicative of motion, physiological data and/or environmental condition, or analysis of such data indicative of motion, physiological data and/or environmental condition according to the principles described herein. In one example, the analyzer 1102 can be disposed on the substrate 1100 with the data receiver 1101, and in another example, the analyzer 1102 is disposed proximate to the substrate 1100 and data receiver 1101.

In the example implementation of the electronic device in FIG. 11A, the analyzer 1102 can be configured to quantify the data indicative of the motion by calculating an energy imparted.

FIG. 11B shows another example electronic device according to the principles disclosed herein that includes a substrate 1100, data receiver 1101, an analyzer 1102, and a storage module 1107. The storage module 1107 can be configured to save data from the data receiver 1101 and/or the analyzer 1102. In some implementations the storage device 1107 is any type of non-volatile memory. For example, the storage device 1107 can include flash memory, solid state drives, removable memory cards, or any combination thereof. In certain examples, the storage device 1107 is removable from the electronic device. In some implementations, the storage device 1107 is local to the electronic device while in other examples it is remote. For example, the storage device 1107 can be internal memory of a smartphone. In this example, the electronic device may communicate with the smartphone via an application executing on the smartphone. In some implementations, the sensor data can be stored on the storage device 1107 for processing at a later time. In some examples, the storage device 1107 can include space to store processor-executable instructions that are executed to analyze the data from the data receiver 1101. In other examples, the memory of the storage device 1107 can be used to store the measured data indicative of motion, physiological data and/or environmental condition, or analysis of such data indicative of motion, physiological data and/or environmental condition according to the principles described herein.

FIG. 11C shows an example electronic device according to the principles disclosed herein that includes a substrate 1100, a data receiver 1101, an analyzer 1102, and a transmission module 1106. The transmission module 1106 can be configured to transmit data from the data receiver 1101, the analyzer 1102, or stored in the storage device 1107 to an external device. In one example, the transmission module 1106 can be a wireless transmission module. For example, the transmission module 1106 can transmit data to an external device via wireless networks, radio frequency communication protocols, Bluetooth, near-field communication, and/or optically using infrared or non-infrared LEDs.

FIG. 11D shows an example system that includes a substrate 1100, a data receiver 1101, an analyzer 1102 and a processor 1107. The data receiver 1101 can receive data related to sensor measurement from an example electronic device. In an example, the example electronic device can be a flexible sensor. The processor 1107 can be configured to execute processor-executable instructions stored in a storage device 1107 and/or within the processor 1107 to analyze data indicative of motion, physiological data and/or environmental condition, or analysis of such data indicative of motion, physiological data and/or environmental condition according to the principles described herein. In some implementations, the data can be directly received from the data receiver 1101 or retrieved from the storage device 1107. In one example, the processor can be a component of the analyzer 1102 and/or disposed proximate to the data receiver 1101. In another example, the processor 1107 can be external to the electronic device, such as in an external device that downloads and analyzes data retrieved from the electronic device. The processor 1107 can execute processor-executable instructions that quantify the data received by the data receiver 1101 in terms of imparted energy.

In an example, multiple differing predetermined thresholds may be used to monitor the motion and/or physiological state of a user, and/or an environmental condition. In some examples, the processor 1107 can maintain counts for each of the bins created by the differing predetermined thresholds and increment the counts when the quantitative measure for the user corresponds to a specific bin. In some examples, the processor 1107 can maintain counts for each of the bins created by the predetermined threshold and increment the counts when a metric is registered that corresponds to a specific bin. The processor 1107 may transmit the cumulative counts for each bin to an external device via the transmission module 1106. Non-limiting example categories include satisfactory, in need of further training, needing to be benched for the remained of the game, unsatisfactory, or any other type of classification.

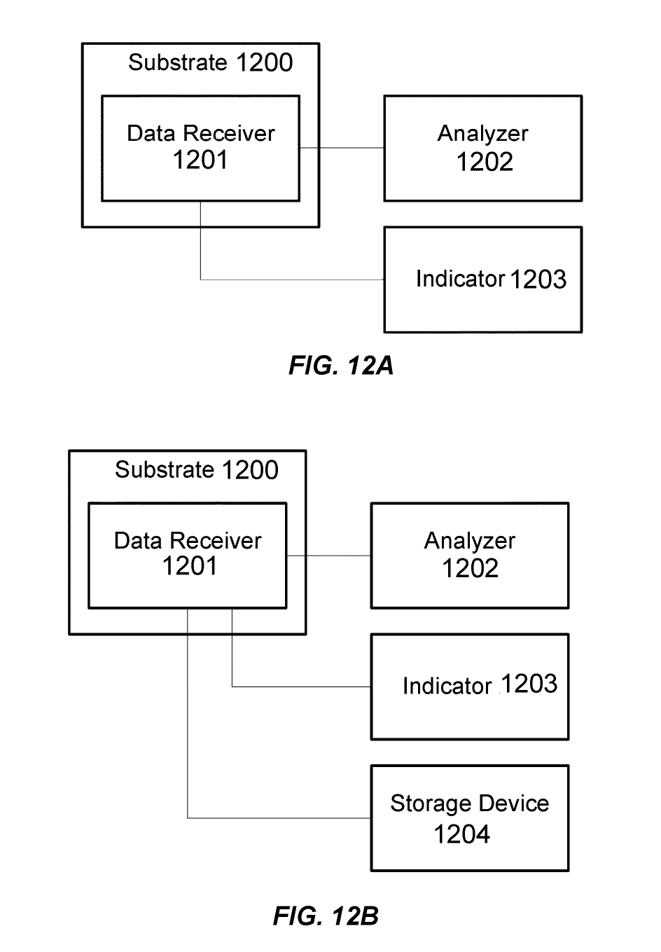

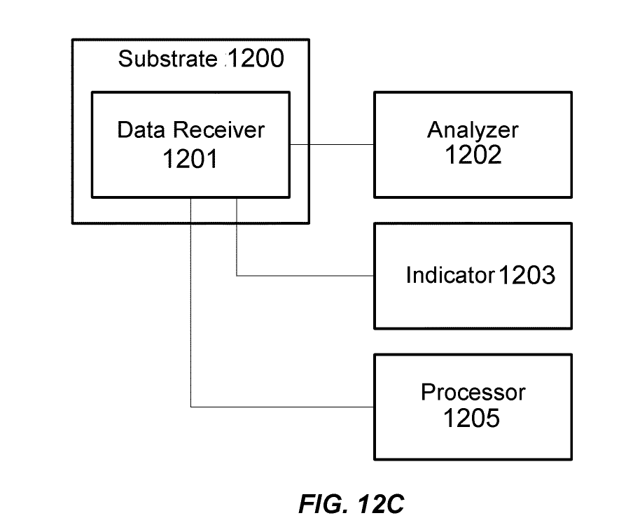

FIGS. 12A-12C show non-limiting examples of possible device configurations including a display for displaying the data or analysis results. The examples of FIGS. 12A-12C include a substrate 1200, a flexible sensor 1201, a analyzer 1202, and an indicator 1203. In different examples the device can include a processor 1205, to execute the processor-executable instructions described herein; and a storage device 1204 for storing processor-executable instructions and/or data from the analyzer 1202 and/or flexible sensor 1201. The example devices of FIGS. 12A-12C also include an indicator 1203 for displaying and/or transmit data indicative of motion, physiological data and/or environmental condition, or analysis of such data indicative of motion, physiological data and/or environmental condition according to the principles described herein, and/or user information.

In one example, the indicator 1203 can include a liquid crystal display, or an electrophoretic display (such as e-ink), and/or a plurality of indicator lights. For example, the indicator 1203 can include a series of LEDs. In some implementations, the LEDs range in color, such as from green to red. In this example, if performance does not meet a pre-determined threshold measure, a red indicator light can be activated and if the performance meets the pre-determined threshold measure, the green indicator light can be activated. In yet another example, the intensity of the LED indicator lights can be correlated to the magnitude of the quantified measure of performance of the user or the bin counts (e.g., as a measure of throw count). For example, the LEDs can glow with a low intensity for quantified performance below a threshold and with a high intensity for quantified performance above the threshold.

In another example, the LEDs of the indicator 1203 may be configured to blink at a specific rate to indicate the level of the quantified metric of the performance of the user, physiological data and/or environmental condition. For example, the indicator may blink slowly for a quantified performance of the user, physiological data and/or environmental condition over a first threshold but below a second threshold and blink at a fast rate for a quantified performance of the user, physiological data and/or environmental condition above the second threshold. In yet another example, the indicator 1203 may blink using a signaling code, such as but not limited to Morse code, to transmit the measurement data and/or data indicative of performance level. In some implementations, as described above, the signaling of the indicator 1203 is detectable to the human eye and in other implementations it is not detectable by the human eye and can only be detected by an image sensor. The indicator 1203 emitting light outside the viable spectrum of the human eye (e.g. infrared) or too dim to be detected are examples of indication methods indictable to the human eye. In some examples, the image sensor used to detect the signals outside the viewing capabilities of a human eye can be the image sensor of a computing device, such as but not limited to a smartphone, a tablet computer, a slate computer, a gaming system, and/or an electronic reader.

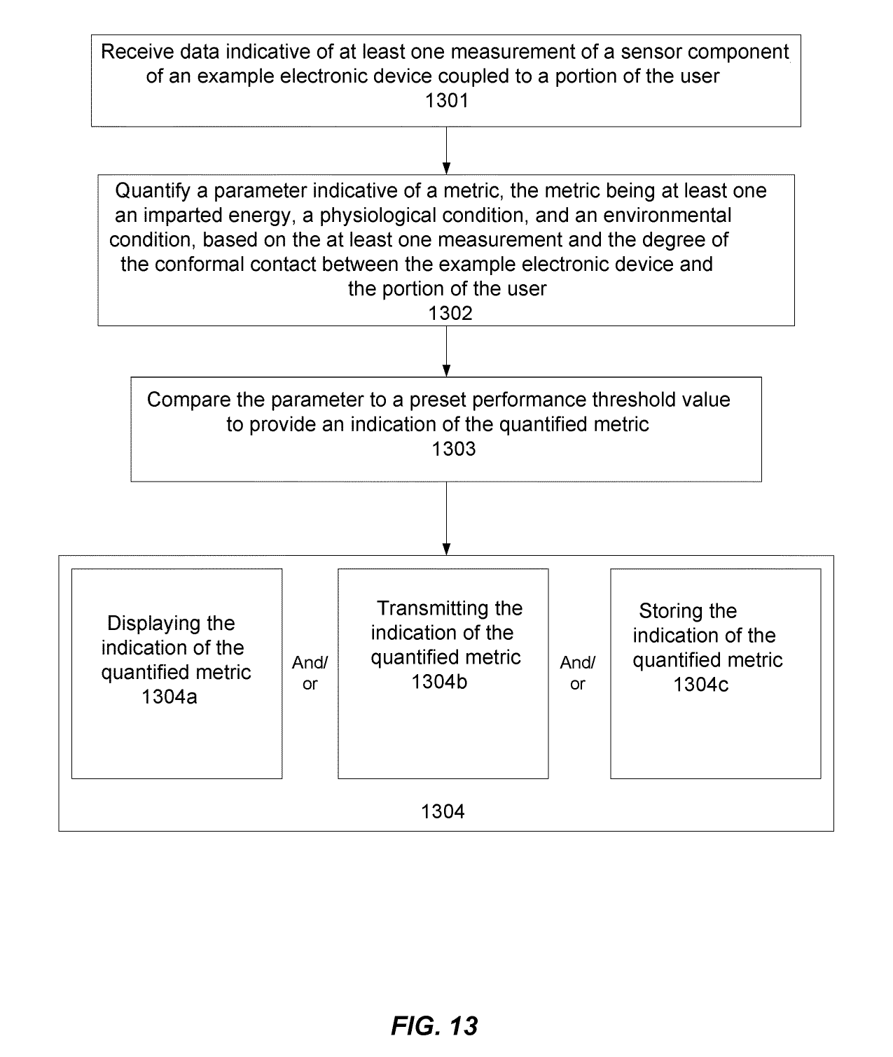

FIG. 13 show a flow chart illustrating a non-limiting example method of quantifying the performance of a user, the physiological data and/or environmental condition, according to the principles described herein.

In block 1301, a processing unit receives data indicative of at least one measurement of a sensor component of an example electronic device coupled to a portion of the user. In an example, the at least one measurement can be acceleration data representative of an acceleration proximate to the portion of the user. In other examples, the at least one measurement includes, but is not limited to, a muscle activation measurement, a heart rate measurement, an electrical activity measurement, a temperature measurement, a hydration level measurement, a neural activity measurement, a conductance measurement, an environmental measurement, and/or a pressure measurement.

The example electronic device is configured to substantially conform to the surface of the portion of the user to provide a degree of conformal contact. The data indicative of the at least one measurement can include data indicative of the degree of the conformal contact In block 1302, the processing unit quantifies a parameter indicative of a metric, the metric being at least one of an imparted energy, a physiological condition, and an environmental condition, based on the at least one measurement and the degree of the conformal contact between the example electronic device and the portion of the user. In some examples, the processing unit may only quantify a metric that has a value of a metric, such as but not limited to an imparted energy, physiological data, and/or environmental condition, above a predetermined threshold value. As described above, in some examples, quantified metrics above a first predetermined threshold may be further categorized responsive to if the value of the metric corresponds to a level that exceeds a second or third predetermined threshold.

In block 1303, the processing unit compares the parameter to a preset performance threshold value to provide an indication of the quantified metric (such as but not limited to an imparted energy, a physiological condition, and an environmental condition).

In block 1304, the device displays, transmits, and/or or stores an indication of the indication of the quantified metric (such as but not limited to an imparted energy, a physiological condition, and an environmental condition). As indicated in FIG. 13, each of 1304a, 1304b, and 1304c can be performed alone or in any combination. In one example, the indicator 1203 can be used to display the indication of the quantified metric (such as but not limited to an imparted energy, a physiological condition, and an environmental condition), to a user or to an external monitor. For example, the device may include a display that displays a graph of data indicative of the metric over time to a user. In another example, the transmitter 106 can be used to transmit, wirelessly or wired, the data indicative of the quantified metric (such as but not limited to an imparted energy, a physiological condition, and an environmental condition). In such an example, the data can be downloaded from the device and analyzed by implementing processor-executable instructions (e.g., via a computer application). In yet another example, the indication of the performance of the user can be stored either locally to the device or on a separate device, such as but not limited to the hard-drive of a laptop.

While the description herein refers to three different predetermined thresholds, it is understood that the system can be configured to assess performance levels based on many more specified threshold levels according to the principles of the examples described herein.

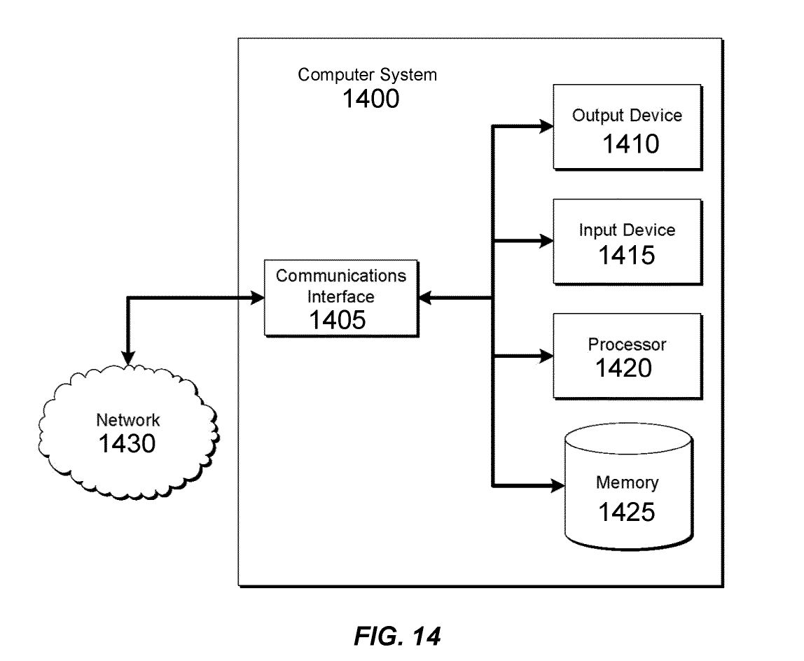

FIG. 14 shows the general architecture of an illustrative computer system 1400 that may be employed to implement any of the computer systems discussed herein. The computer system 1400 of FIG. 14 includes one or more processors 1420 communicatively coupled to memory 1425, one or more communications interfaces 1405, and one or more output devices 1410 (e.g., one or more display units) and one or more input devices 1415.

In the computer system 1400 of FIG. 14, the memory 1425 may include any computer-readable storage media, and may store computer instructions such as processor-executable instructions for implementing the various functionalities described herein for respective systems, as well as any data relating thereto, generated thereby, or received via the communications interface(s) or input device(s). The processor(s) 1420 shown in FIG. 14 may be used to execute instructions stored in the memory 1425 and, in so doing, also may read from or write to the memory various information processed and or generated pursuant to execution of the instructions.

The processor 1420 of the computer system 1400 shown in FIG. 14 also may be communicatively coupled to or control the communications interface(s) 1405 to transmit or receive various information pursuant to execution of instructions. For example, the communications interface(s) 1405 may be coupled to a wired or wireless network (1430), bus, or other communication means and may therefore allow the computer system 1400 to transmit information to and/or receive information from other devices (e.g., other computer systems). While not shown explicitly in the system of FIG. 14, one or more communications interfaces facilitate information flow between the components of the system 1400. In some implementations, the communications interface(s) may be configured (e.g., via various hardware components or software components) to provide a website as an access portal to at least some aspects of the computer system 1400.

The output devices 1410 of the computer system 1400 shown in FIG. 14 may be provided, for example, to allow various information to be viewed or otherwise perceived in connection with execution of the instructions. The input device(s) 1415 may be provided, for example, to allow a user to make manual adjustments, make selections, enter data or various other information, or interact in any of a variety of manners with the processor during execution of the instructions.

According the principles disclosed herein, both the communication module and the analyzer can be disposed in the same electronic device. In another example, the communication module may be integrated with the example electronic device. In this example, the example electronic device may communicate with the analyzer wirelessly, using LEDs, or any other communication means. In some examples, the analyzer may be disposed proximate to the communication module or the analyzer can be a component of a monitoring device to which the measurement data collected by the communication module is transferred.

In an example, the communication module can include a near-field communication (NFC)-enabled component.

In a non-limiting example, the systems, methods and apparatus described herein for providing an indication of the performance of the user may be integrated with an example electronic device that provides the measurement data. In this example, the example electronic device may communicate with the analyzer wirelessly or using an indicator. Non-limiting examples of indicators include LEDs or any other communication means.

In a non-limiting example, the example electronic device includes one or more electronic components for obtaining the measurement data. The electronic components include a sensor component (such as but not limited to an accelerometer or a gyroscope). The electronics of the example electronic device can be disposed on a flexible and/or stretchable substrate and coupled to one another by stretchable interconnects. The stretchable interconnect may be electrically conductive or electrically non-conductive. According to the principles herein, the flexible and/or stretchable substrate can include one more of a variety of polymers or polymeric composites, including polyimides, polyesters, a silicone or siloxane (e.g., polydimethylsiloxane (PDMS)), a photo-patternable silicone, a SU8 or other epoxy-based polymer, a polydioxanone (PDS), a polystyrene, a parylene, a parylene-N, an ultrahigh molecular weight polyethylene, a polyether ketone, a polyurethane, a polyactic acid, a polyglycolic acid, a polytetrafluoroethylene, a polyamic acid, a polymethyl acrylate, or any other flexible materials, including compressible aerogel-like materials, and amorphous semiconductor or dielectric materials. In some examples described herein, the flexible electronics can include non-flexible electronics disposed on or between flexible and/or stretchable substrate layers, such as but not limited to discrete electronic device islands interconnected using the stretchable interconnects. In some examples, the one or more electronic components can be encapsulated in a flexible polymer.

In any of the examples described herein, the electrically conductive material (such as but not limited to the material of the electrically conductive stretchable interconnect and/or an electrical contact) can be, but is not limited to, a metal, a metal alloy, a conductive polymer, or other conductive material. In an example, the metal or metal alloy of the coating may include but is not limited to aluminum, stainless steel, or a transition metal, and any applicable metal alloy, including alloys with carbon. Non-limiting examples of the transition metal include copper, silver, gold, platinum, zinc, nickel, titanium, chromium, or palladium, or any combination thereof. In other non-limiting examples, suitable conductive materials may include a semiconductor-based conductive material, including a silicon-based conductive material, indium tin oxide or other transparent conductive oxide, or Group III-IV conductor (including GaAs). The semiconductor-based conductive material may be doped.

In any of the example structures described herein, the stretchable interconnects can have a thickness of about 0.1 μm, about 0.3 μm, about 0.5 μm, about 0.8 μm, about 1 μm, about 1.5 μm, about 2 μm, about 5 μm, about 9 μm, about 12 μm, about 25 μm, about 50 μm, about 75 μm, about 100 μm, or greater.

In an example system, apparatus and method, the stretchable interconnects can be formed from a non-conductive material and can be used to provide some mechanical stability and/or mechanical stretchability between components of the conformal electronics (e.g., between device components). As a non-limiting example, the non-conductive material can be formed based on a polyimide.

In any of the example devices according to the principles described herein, the non-conductive material (such as but not limited to the material of a stretchable interconnect) can be formed from any material having elastic properties. For example, the non-conductive material can be formed from a polymer or polymeric material. Non-limiting examples of applicable polymers or polymeric materials include, but are not limited to, a polyimide, a polyethylene terephthalate (PET), a silicone, or a polyeurethane. Other non-limiting examples of applicable polymers or polymeric materials include plastics, elastomers, thermoplastic elastomers, elastoplastics, thermostats, thermoplastics, acrylates, acetal polymers, biodegradable polymers, cellulosic polymers, fluoropolymers, nylons, polyacrylonitrile polymers, polyamide-imide polymers, polyarylates, polybenzimidazole, polybutylene, polycarbonate, polyesters, polyetherimide, polyethylene, polyethylene copolymers and modified polyethylenes, polyketones, poly(methyl methacrylate, polymethylpentene, polyphenylene oxides and polyphenylene sulfides, polyphthalamide, polypropylene, polyurethanes, styrenic resins, sulphone based resins, vinyl-based resins, or any combinations of these materials. In an example, a polymer or polymeric material herein can be a DYMAX® polymer (Dymax Corporation, Torrington, Conn.). or other UV curable polymer, or a silicone such as but not limited to ECOFLEX® (BASF, Florham Park, N.J.).

In any example herein, the non-conductive material can have a thickness of about 0.1 μm, about 0.3 μm, about 0.5 μm, about 0.8 μm, about 1 μm, about 1.5 μm, about 2 μm or greater. In other examples herein, the non-conductive material can have a thickness of about 10 μm, about 20 μm, about 25 μm, about 50 μm, about 75 μm, about 100 μm, about 125 μm, about 150 μm, about 200 μm or greater.

In the various examples described herein, the example electronic device includes at least one sensor component, such as but not limited to an accelerometer and/or a gyroscope. In one example, the data receiver can be configured to detect acceleration, change in orientation, vibration, g-forces and/or falling. In some examples, the accelerometer and/or gyroscope can be fabricated based on commercially available, including “commercial off-the-shelf” or “COTS” electronic devices that are configured to be disposed in a low form factor conformal system The accelerometers may include piezoelectric or capacitive components to convert mechanical motion into an electrical signal. A piezoelectric accelerometer may exploit properties of piezoceramic materials or single crystals for converting mechanical motion into an electrical signal. Capacitive accelerometers can employ a silicon micro-machined sensing element, such but not limited to a micro-electrical-mechanical system, or MEMS, sensor component. A gyroscope can be used to facilitate the determination of refined location and magnitude detection. As a non-limiting example, a gyroscope can be used for determining the tilt or inclination of the body part to which it is coupled. As another example, the gyroscope can be used to provide a measure of the rotational velocity or rotational acceleration of the body part (such as an arm in a throwing motion, including a hitting or kicking motion, a cycling motion, or a swimming motion). For example, the tilt or inclination can be computed based on integrating the output (i.e., measurement) of the gyroscope.

An example system including an electronic device according to the principles described herein can be configured to provide a variety of sensing modalities. The example system can be configured with sub-systems such as telemetry, power, power management, processing as well as construction and materials. A wide variety of multi-modal sensing systems that share similar design and deployment can be fabricated based on the example electronic devices.

In another example, the system for quantifying performance of a user can include a transmission module. The transmission module can be configured to transmit the data indicative of the quantified metric and/or the measurement data to an external device. For example, the transmission module can transmit the data indicative of the quantified metric and/or the measurement data to a computing device such as but not limited to a smartphone (such as but not limited to an Iphone®, an Android™ phone, or a Blackberry®), a tablet computer, a slate computer, an electronic gaming system (such as but not limited to an XBOX®, a Playstation®, or a Wii®), and/or an electronic reader. The analyzer may be processor-executable instructions implemented on the computing device. In another example, the transmission module can transmit data using a communication protocol based on Bluetooth® technology, Wi-Fi, Wi-Max, IEEE 802.11 technology, a radio frequency (RF) communication, an infrared data association (IrDA) compatible protocol, or a shared wireless access protocol (SWAP).

In some examples, the processor-executable instructions can include instructions to cause the processor to maintain counts for each of a number of bins created by differing predetermined thresholds as described herein. A bin count can be increment when the quantitative measure of the performance of the user corresponds to a specific bin. In some examples, the processor-executable instructions can include instructions to cause the processor to maintain counts for each of the bins created by the predetermined threshold and increment the counts when a quantified metric is registered corresponding to a specific bin. As a non-limiting example, a first bin may include the quantitative measure of the performance for a specific imparted energy above a first threshold but below a second threshold, a second bin may include the quantitative measure of the performance with an imparted energy value above the second threshold but below a third threshold, and a third bin may include any quantitative measures of the performance with an imparted energy value above the third threshold. The processor-executable instructions can include instructions to cause the processor to transmit the cumulative counts for each bin to an external device via a transmission module. The counts for each bin can be reset at predetermined intervals. For example, processor-executable instructions can include instructions to cause the processor to track the number of counts for each bin an athlete registers over a time period, and the counts from the bins may be used as an overall rating of the performance of the user. In another example, the cumulative count of a bin, such as but not limited to a bin indicative of poorer performance, may be used to indicate a physical condition of the user. For example, the cumulative count in the bin indicative of poorer performance may be used to indicate that a user should rest or should be benched within a certain period of time.

In a human readable example, the indicator may include LEDs that blink or glow at a specific color to indicate the quantified metric, including the quantified metric of the performance of the user, physiological data and/or environmental condition. In this example, the indicator can be used to blink (turn on and off) a detectable sequence of light flashes that corresponds to the quantified metric above a predetermined threshold. A sequence of on and off flashes can be counted to give a specific number. As a non-limiting example, the sequence <on>, <off>, <on>, <off>, <on>, <off>, could correspond to 3 instances of quantified performance above the threshold. For double-digits (above 9 instances of quantified performance) the numbers might be indicated thusly: <on>, <off>, <pause>, <on>, <off>, <on>, <off> would correspond to 12 instances of quantified performance using decimal notation. While a useful duration of the <on> pulses could be in the range of 10-400 milliseconds, any observable duration can be used. The <pause> should be perceptibly different from than the <on> signal (including being longer or shorter) to indicate the separation of numbers. This sequence of displayed values can be triggered but not limited to a specific action or sequence related to obtaining the displayed values such as a reset or power off and power on sequence.

In yet another example, the indicator can be configured to provide a non-human readable indicator in addition to, or in place of, the human readable indicator. For example, a smartphone application (or other similar application of processor-executable instructions on a computing device) can be used to read or otherwise quantify an output of an indicator using a camera or other means. For example, where the indicator provides an indication or transmits information using LEDs, the camera or other imaging component of a smartphone or other computing device may be used to monitor the output of the indicator. Examples of non-human readable interfaces using an LED include blinking the LED at a rate that cannot be perceived by the human eye, LEDs that emit electromagnetic radiation outside of the visual spectrum such as infrared or ultraviolet, and/or LEDs that glow with low luminosity such that they cannot be perceived by a human.

Non-limiting examples of computing devices herein include smartphones, tablets, slates, e-readers, or other portable devices, of any dimensional form factor (including mini), that can be used for collecting data (such as, but not limited to, a count and/or measures of performance) and/or for computing or other analysis based on the data (such as but not limited to computing the count, calculating imparted energy, and/or determining whether a measure of performance is above or below a threshold). Other devices can be used for collecting the data and/or for the computing or other analysis based on the data, including computers or other computing devices. The computing devices can be networked to facilitate greater accessibility of the collected data and/or the analyzed data, or to make it generally accessible.

In another non-limiting example, the performance monitor can include a reader application including a computing device (such as but not limited to a smartphone-, tablet-, or slate-based application), that reads the LED display from an indicator, calculates tiered counts from tiered indications of the indicator for the metric, and logs the data to the memory of the monitor. In a non-limiting example, the tiered indication may be a green light indication for a quantified metric as reaching a first threshold, a yellow light indication for quantified metric as reaching a second threshold, and red light indication for quantified metric as reaching a third threshold, or any combination thereof. The application can be configured to display the counts, or indicate a recommendation for future activity. The example system and apparatus can be configured to send data and performance reports to selected recipients (with appropriate consent) such as but not limited to parents, trainers, coaches, and medical professionals. The data can also be aggregated over time to provide statistics for user players, groups of players, entire teams or for an entire league. Such data can be used to provide information indicative of trends in game play, effects of rule changes, coaching differences, differences in game strategy, and more.

In any example provided herein where the subject is a user, it is contemplated that the system, method or apparatus has obtained the consent of the user, where applicable, to transmit such information or other report to a recipient that is not the user prior to performing the transmission.

Wearable electronics devices can be used to sense information regarding particular motion events (including other physiological measures). Such motion indicator devices, including units that are thin and conformal to the body, can provide this information to users and others (with appropriate consent) in a variety of ways. Some non-limiting examples include wireless communication, status displays, haptic and tactile devices, and optical communication. In the case of a motion indicator, such as that described in U.S. patent application Ser. No. 12/972,073, 12/976,607, 12/976,814, 12/976,833, and/or 13/416,386, each of which is incorporated herein by reference in its entirety including drawings, the wearable electronics device described herein can be used to register and store numbers of instances of quantified performance above a threshold, or other physiological data, onboard.

As a non-limiting example of a smart lighting devices that may be applicable to a hit count monitor according to the principles described herein, U.S. Pat. No. 6,448,967, titled “Universal Lighting Network Methods and Systems,” which is incorporated herein by reference in its entirety including drawings, describe a device that is capable of providing illumination, and detecting stimuli with sensors and/or sending signals. The smart lighting devices and smart lighting networks may be used for communication purposes.

In an example implementation, a thin, flexible, and bendable band is provided that has a snap close feature for wearing around a body part of a user, such as but not limited to a user's wrist, arm, neck, thigh, knee, torso and/or ankle. The example band including an electronic device described herein can be used as a wearable health and/or fitness monitor that is one size fits all. The example electronic device can be formed in a unique form factors that allow a user to manipulate the encapsulation without damaging the internal components.

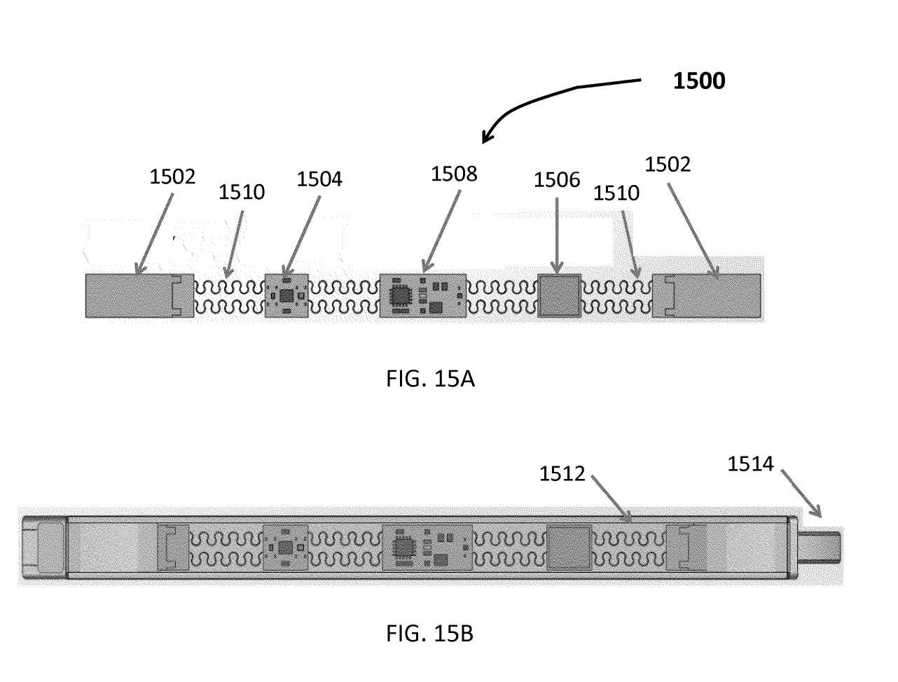

FIG. 15A shows components of an example electronic device 1500 according to the principles herein. The example electronic device 1500 includes batteries 1502, a charger 1504, and a capacitive component 1506, disposed on device islands. The example electronic device 1500 also includes multiple components (a BLTE component, LEDs, and an accelerometer) on a single device island 1508. Stretchable interconnects 1510 couple to the device islands. Capacitive component 1506 can cerve as a cap touch sensor on the band. A depression can be disposed over the cap touch button, to allow cap sensing through silicone and help a user to locate the region. At least one component of the band can be encapsulated in, e.g., flexible and/or stretchable encapsulant, such as but not limited to a polymer material. The encapsulating material can be water-resistant.

FIG. 15B shows the example electronic device 1500 encapsulated in an encapsulant 1512. The example band can be configured to include a micro USB 1514 at the end of the band. The micro USB can be plugged into a computer (e.g., to transfer and/or receive data) and/or charging device/platform.

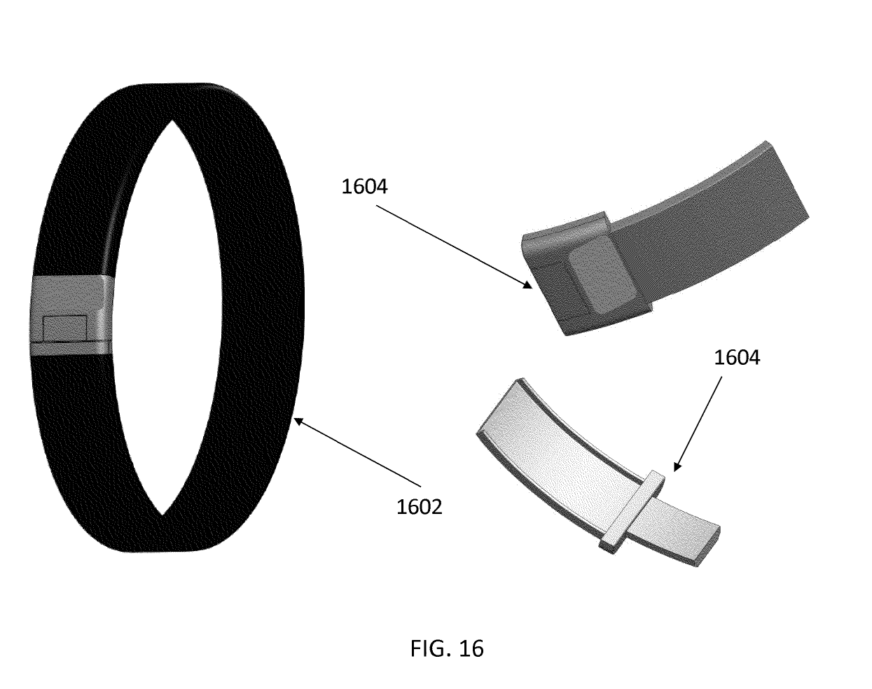

FIG. 16 shows a non-limiting example of an electronic device formed as a band 1602 that includes a micro USB clasping system 1604. The band 1602 is configured t have a substantially elliptical shape.

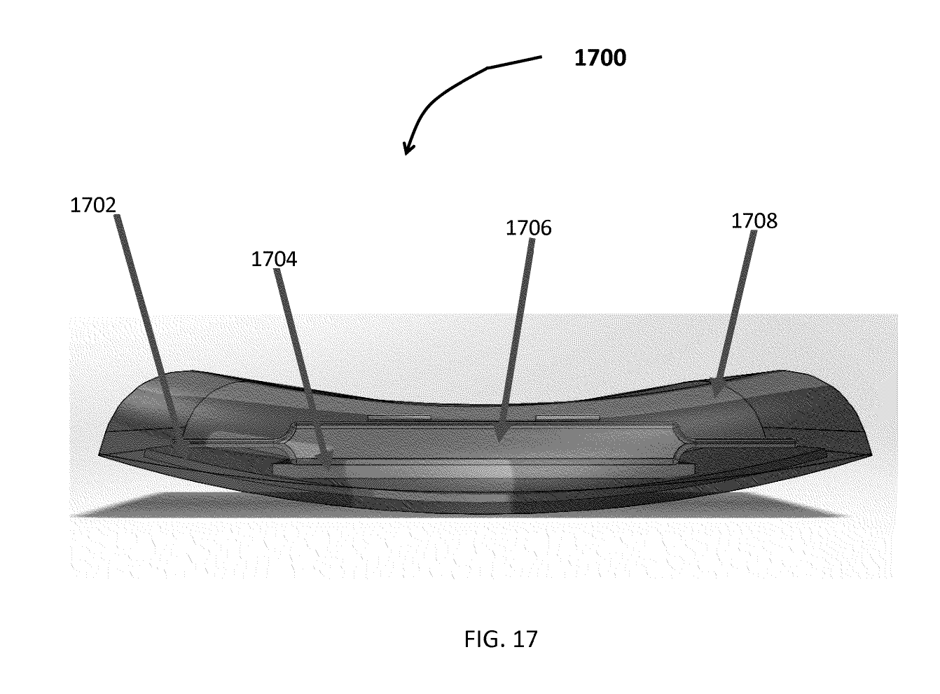

FIG. 17 shows a non-limiting example of an electronic device 1700 formed as a band. The example electronic device is shown is a curved conformation. The example band 1700 includes a biastable structure, an electronic circuit, a battery, and an encapsulant.

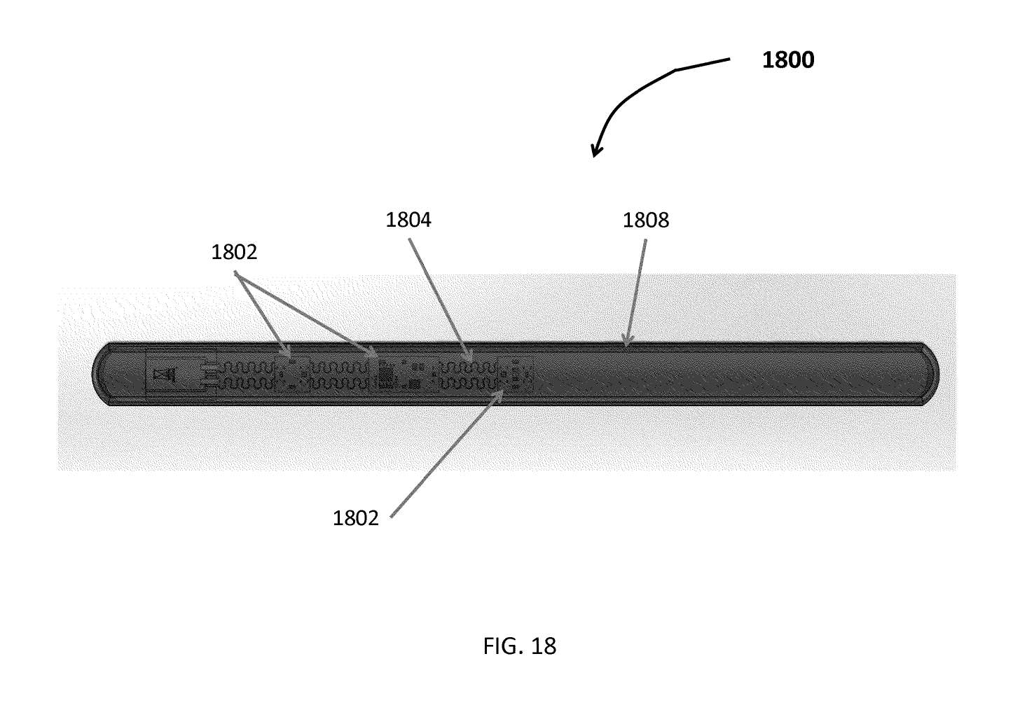

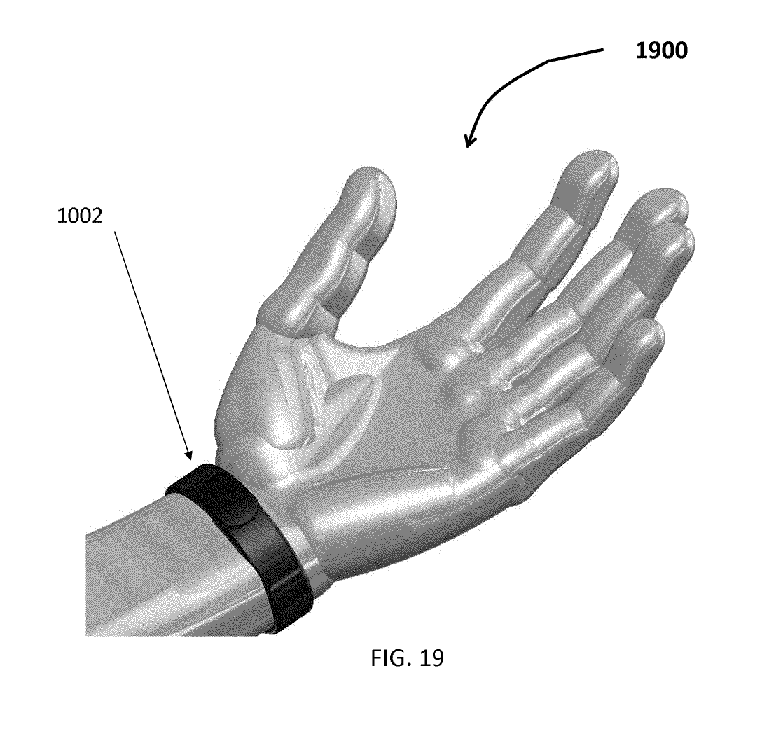

FIG. 18 shows components of an example electronic device 1800 according to the principles herein. The example electronic device 1800 includes electronic components disposed on device islands 1802, and stretchable interconnects 1804 couple to the device islands. The band includes an encapsulant 1806 encapsulating the device islands and stretchable interconnects.

FIG. 19 shows an example electronic device that is in a coiled configuration about the wrist of a user.

In an example, an antenna can be mounted on the back of at least one of the device islands. At least one of the example device islands can include at least one microprocessor and/or at least one dipole antenna. At least two different silicone durometers can be used for encapsulating.

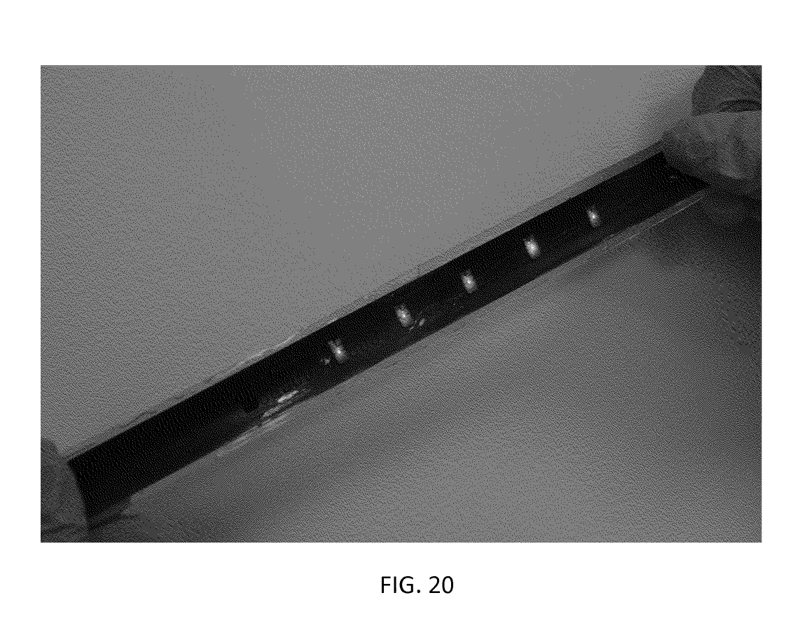

In various example electronic devices, the encapsulant can be a silicone over the LEDs, which can have low opacity, to the possibility of being substantially transparent FIGS. 20-25 show differing views and conformations of an example electronic device according to the principles described herein. Each of FIGS. 20-25 shows example electronic devices that include a bistable band, LEDs disposed about the band, portions of the electronic circuit integrated with the LEDs. In these examples, the bistable structure also functions to limit and regulate a deformation of the structure. That is, the properties of the bistable band, and known extended and coiled conformations, can be exploited to limit the degree of deformation of the stretchable interconnects, junction regions, and device islands, and potentially prevent the strain-sensitive portions of the system (including the junction region) from being subjected to excessive strain.

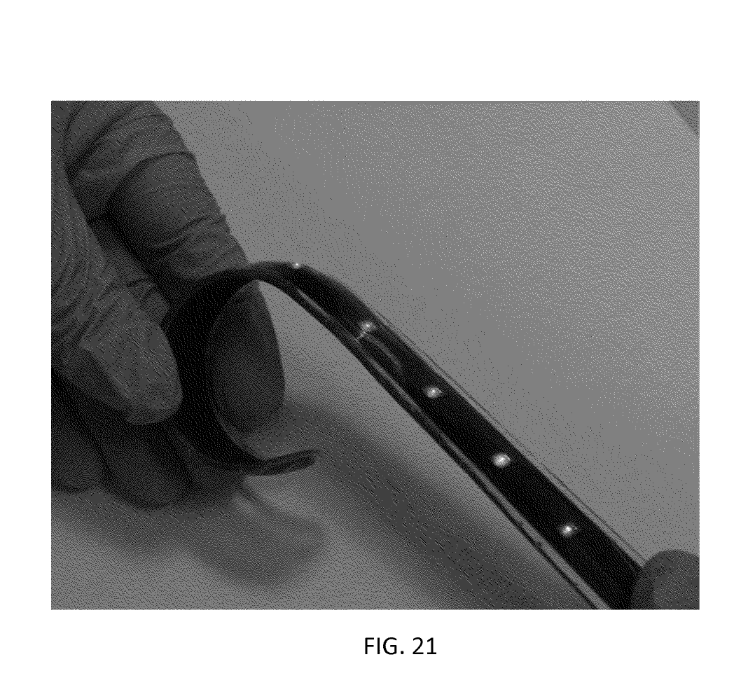

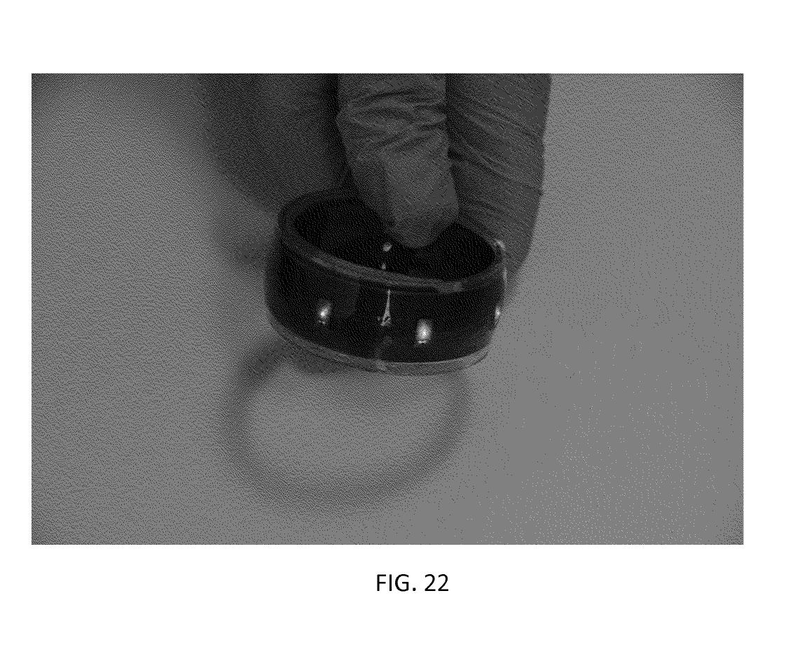

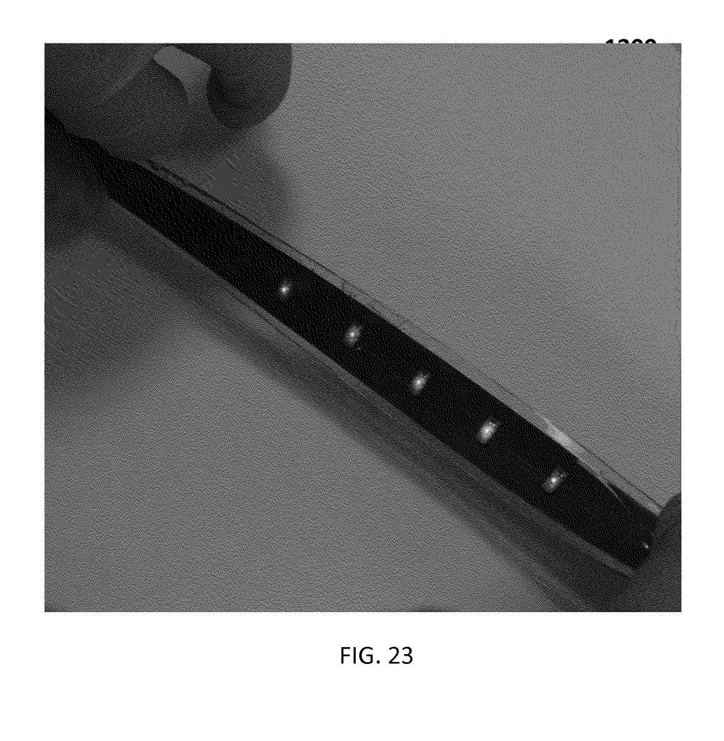

FIGS. 20-23 show the example electronic device in various conformations. FIG. 20 shows the example electronic device in the extended conformation. FIG. 21 shows the example electronic device with a portion in the curved conformation. FIG. 22 shows the example electronic device in a curved conformation that is a coiled conformation. FIG. 23 shows the example electronic device that is restored to the extended conformation.

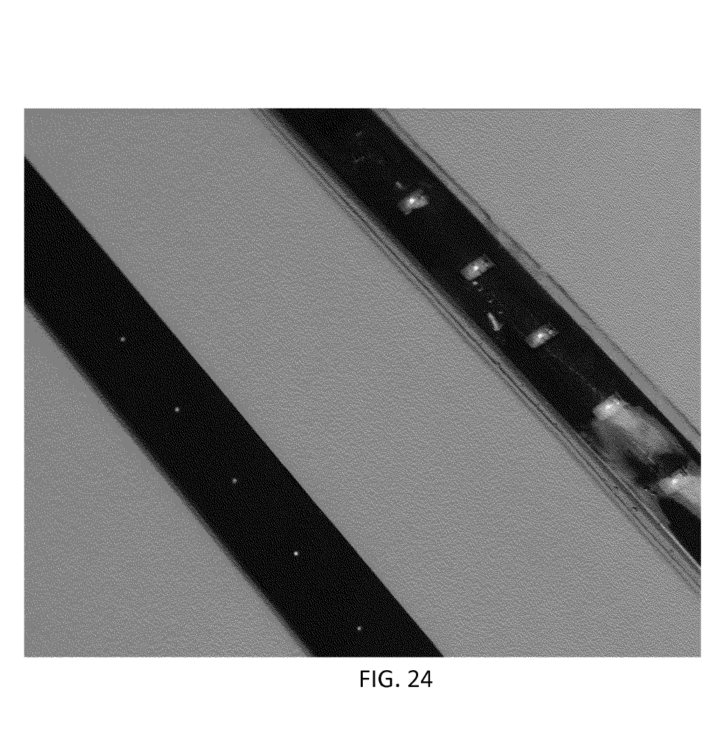

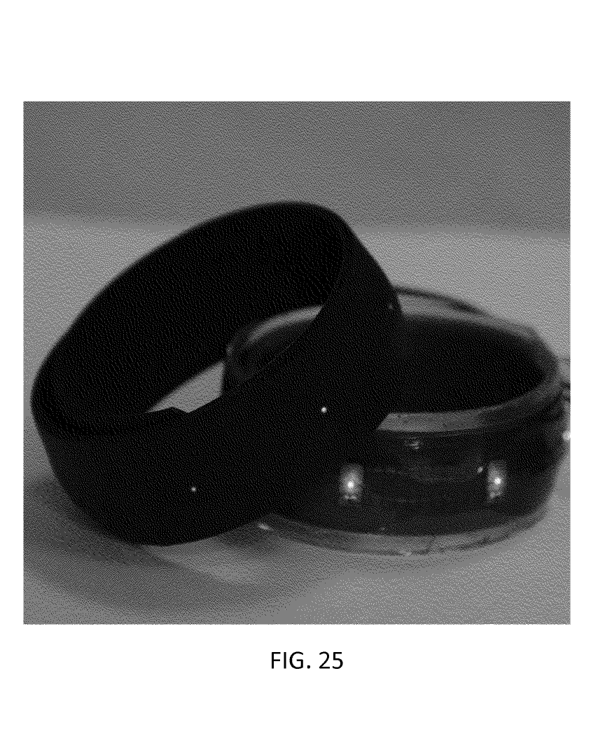

FIGS. 24 and 25 show example electronic devices with differing types of encapsulation materials, i.e., one having an encapsulation material that is partially transparent and the other having an encapsulation material that is opaque. FIG. 24 shows both example electronic devices in the extended conformation. FIG. 25 shows both example electronic devices in a curved conformation that is a coiled conformation.

The example electronic devices herein can be configured to closely couple to the skin of a user for monitoring physiological parameters such as but not limited to movement, heart rate, body temperature, etc. The example band including the electronic device can be used to provide visual indications of the measured parameter(s).

In an example implementation, an example electronic device can be formed as a band including at least one light-emitting device (LED) that can be worn around the ankle or other body part of a cyclist to also keep the trouser legs from getting caught in a portion of the bicycle (e.g., chain), as well as serving as a visual indicator to drivers of the cyclist.

In an example implementation, the change in conformation of an example electronic device can be activated based on the mechanical feature of a bistable spring band that has a flat “open” position and a circular clasped “closed” position. The rigid diameter/dimensions in the circular clasped “closed” position can be adjusted in order to fit differing sizes of users, or differing portions of body parts of a user.

In an example implementation, the electronic device according to the principles herein can be configured to include a bistable spring band that acts as a regulator of a bending deformation, a twisting deformation, and/or a stretching deformation of the electronic device, including serving to limit the extent of the bending deformation, the twisting deformation, and/or the stretching deformation.

The use of the bistable structure as described herein can obviate the need for a locking mechanism or a required connection clasp to mount the example electronic device to a portion of a body part of a user.

In a non-limiting example, the example electronic device can be configured such that the slapping and/or clasping of the electronic device about a body part activates (i.e., powers ON) the example electronic device. For example, the slapping and/or clasping of the electronic device can trigger a mechanism to turn on components such as an integrated circuit, one or more LEDs, one or more accelerometer(s), etc. In an example, the method of activating the electronic device using the triggering mechanism can utilize components such as but not limited to contact pads, a mechanical snap switch, a dome switch, magnets, etc.

In a non-limiting example, the example electronic device can be configured such that an opening and/or flattening of the band de-activates (i.e., power off) one or more components of the example electronic device (such as but not limited to the integrated circuit, one or more LEDs, one or more accelerometer(s), etc).

In an example implementation, multiple charging, data, and phone transfer modes can be integrated into the band of the example electronic device. For example, the band can be configured to include a micro USB encapsulated in the end of the band, to be plugged into a computer and/or charging device/platform.

In an example implementation, the electronic device includes a wireless coil that has the conformation of an open wire when the electronic device is in the extended conformation (a first stable flat orientation), and curls into a charging coil when the electronic device is in the curved conformation (the second stable circular/closed position). The electronic device in the closed/circular position could be hung around a charging rod or simply placed on a charging platform.

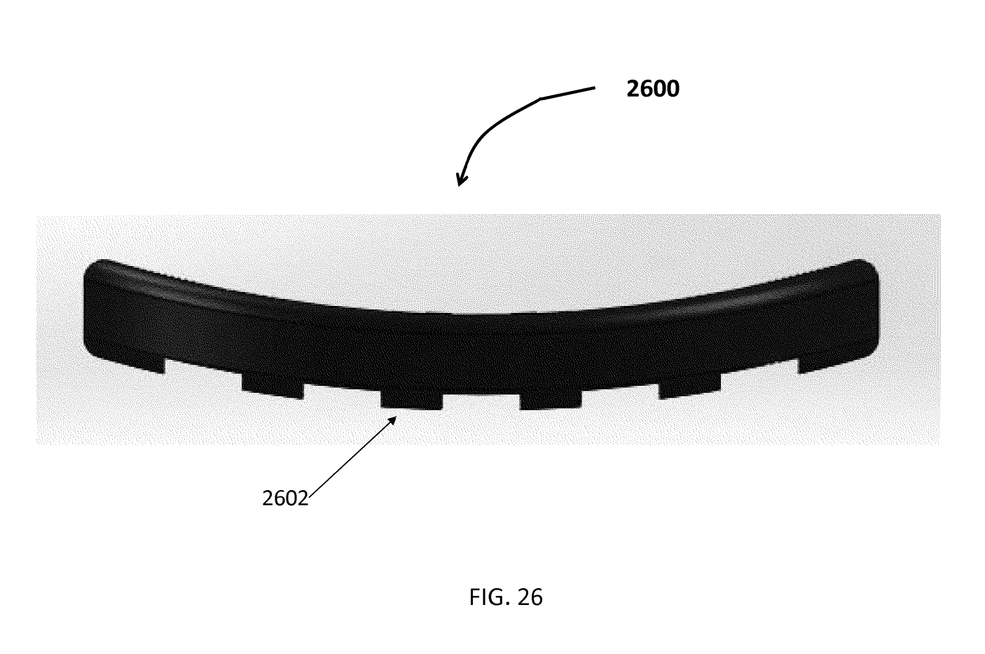

FIG. 26 shows the cross-section of an example electronic device 2600 formed as a band. As shown in FIG. 26, the example electronic device 2600 can include raised features 2602 formed on a surface of the band that is expected to be proximate to the skin. The features 2602 facilitate greater ventilation, breathability, and comfort, through breathability to body heat and sweat.

The example systems, methods and apparatus herein can be implemented in various application. Non-limiting examples applications include function as force load cells, use as sensors that detect flow rate, use as MEM's based accelerometers to measure tremors in patients with Parkinson's etc, use as piezoelectric sensors for sleep apnea, use as temperature sensors to measure skin temperature and/or body temperature, use to quantify cicotine or insulin absorption, or use of color changing for monitoring mood, temperature, heart rate, blood pressure, weather etc. In an example, the color changing could be the lighting in the room, LED's on a measurement patch, display on a TV, video games, fitness etc). As other non-limiting example applications include energy harvesting from snapping/moving the band (similar to a self-winding watch), measuring cardiac electricity, muscle electricity, stomach electricity, skin electricity, nerve electricity, measuring chemical and hormone balances, locating veins, function as action lights for biking, running etc., location monitoring for children, use as environmental detector for hazardous chemicals in example CFC's, VOC's, and ozone.

In the various example implementations, the example electronic devices can be used for measuring UV exposure, as a speedometer, measure humidity, act as a GPS, measure altitude, serve as a breathalyzer, a carbon monoxide detector, a compass, or a proximity sensor.

The stainless steel bistable spring band bend limiter is integrated into the stretchable circuit encapsulation providing a unique form factor for wearable electronics. In a single motion, the user can easily and uniquely clasp the band by slapping it against their wrist to close. The size of the user's wrist is independent from the closing feature of the band due to its “one size fits all” aspect. The bistable band can act as a bend, twist, and strain limiter for the internal electronics.

TABLE I
Non-Limiting Example Implementations

| | Features | | | |
|---|---|---|---|---|
| Components | Example 1* | Example 2* | Example 3* | Notes |
| Display | 10 LEDs | 1 RGB or 3 LEDs | 3 LEDs | Shines through |
| | | | | transparent or |
| | | | | semi- |
| | | | | transparent |
| | | | | portion of band |
| | | | | surface |
| Communication | BLE (10 m range) | BLE (2 m range) | NFC | |
| Interface | | | | |
| Battery Life | 5 days | 3 days | 1 day | If rechargeable |
| | 12 months | 6 months | 4 months | If non- |
| | | | | rechargeable |
| Charge | | USB or wireless | wired | If rechargeable |
| Interface | | | | |
| Recharge time | Less than about | Less than about | Less than about | |
| | 30 minutes | 1.5 hours | 2 hours | |
| Data Storage | 5 recharge cycles | 3 recharge | 2 recharge | If rechargeable |
| | worth | cycles worth | cycles worth | |
| | 14 days | 7 days | 4 days | If non- |
| | | | | rechargeable |
| Thickness | 2.5 mm | 4 mm | 6 mm | |
| Form Factor/ | All curved and | Entirely curved | One or more | |
| Conformation | flexible | | flat, rigid | |
| | | | sections | |
| Flex Cycles | About 100000 | About 50000 | About 10000 | Min: worn and |
| | | | | removed 4 |
| | | | | times per days |
| | | | | for about 3 |
| | | | | years |
| Bend radius | 5 mm | 10 mm | 25 mm | Radius on |
| | | | | deforming the |
| | | | | band, e.g., by |
| | | | | flexing |
| Closure type | None used | Current or | Clasp or other | |
| | | magnetic | watch-style | |
| | | closure | | |
| Visual | Color (including | Color (including | Color (including | |
| appearance of | black or white) | black or white) | black or white) | |
| band | transparent or | transparent or | transparent or | |
| | semi- | semi- | semi- | |
| | transparent | transparent | transparent | |
| | (clear) | (clear) | (clear) | |
| Projected | 4 years | 3 years | 2 years | |
| lifetime | | | | |

Each non-limiting example system includes at least one accelerometer, such as but not limited to a 3-axis accelerometer.

Examples of the subject matter and the operations described herein can be implemented in digital electronic circuitry, or in computer software, firmware, or hardware, including the structures disclosed in this specification and their structural equivalents, or in combinations of one or more of them. Examples of the subject matter described herein can be implemented as one or more computer programs, i.e., one or more modules of computer program instructions, encoded on computer storage medium for execution by, or to control the operation of, data processing apparatus. The program instructions can be encoded on an artificially generated propagated signal, e.g., a machine-generated electrical, optical, or electromagnetic signal, that is generated to encode information for transmission to suitable receiver apparatus for execution by a data processing apparatus. A computer storage medium can be, or be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or be included in, one or more separate physical components or media (e.g., multiple CDs, disks, or other storage devices).

The operations described in this specification can be implemented as operations performed by a data processing apparatus on data stored on one or more computer-readable storage devices or received from other sources.

The term “data processing apparatus” or “computing device” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them.

A computer program (also known as a program, software, software application, script, application or code) can be written in any form of programming language, including compiled or interpreted languages, declarative or procedural languages, and it can be deployed in any form, including as a stand alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatuses can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor receives instructions and data from a read only memory or a random access memory or both. The essential elements of a computer are a processor for performing actions in accordance with instructions and one or more memory devices for storing instructions and data. Generally, a computer can include, or be operatively coupled to receive data from or transfer data to, or both, one or more mass storage devices for storing data, e.g., magnetic, magneto optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), for example. Devices suitable for storing computer program instructions and data include all forms of non volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, examples of the subject matter described herein can be implemented on a computer having a display device, e.g., a CRT (cathode ray tube), plasma, or LCD (liquid crystal display) monitor, for displaying information to the user and a keyboard and a pointing device, e.g., a mouse, touch screen or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

Examples of the subject matter described herein can be implemented in a computing system that includes a back end component, e.g., as a data server, or that includes a middleware component, e.g., an application server, or that includes a front end component, e.g., a client computer having a graphical user interface or a Web browser through which a user can interact with an implementation of the subject matter described in this specification, or any combination of one or more such back end, middleware, or front end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system such as system 400 or system 100 can include clients and servers. A client and server are generally remote from each other and typically interact through a communication network. The relationship of client and server arises by virtue of computer programs running on the respective computers and having a client-server relationship to each other. In some examples, a server transmits data to a client device (e.g., for purposes of displaying data to and receiving user input from a user interacting with the client device). Data generated at the client device (e.g., a result of the user interaction) can be received from the client device at the server.

While this specification contains many specific implementation details, these should not be construed as limitations on the scope of any inventions or of what may be claimed, but rather as descriptions of features specific to particular embodiments of the systems and methods described herein. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In some cases, the actions recited in the claims can be performed in a different order and still achieve desirable results. In addition, the processes depicted in the accompanying figures do not necessarily require the particular order shown, or sequential order, to achieve desirable results.

In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

What is claimed is:

1. An electronic device, comprising:
a band comprising a bistable structure, wherein the bistable structure has an extended conformation and a curved conformation, and wherein the band has a first surface;
a functional layer disposed over the first surface, the functional layer comprising:
at least one device island; and
at least one stretchable interconnect coupled to the at east one device island at a junction region;
one or more neutral mechanical surface adjusting layers disposed over at least a portion of the functional layer; and
one or more encapsulating layers disposed over the one or more neutral mechanical surface adjusting layers;
wherein the one or more neutral mechanical surface adjusting layers have a property that is spatially inhomogeneous relative to a location in the electronic device; and
wherein the at least one device island and at least one stretchable interconnect are disposed about the band such that the at least one device island and the junction region are disposed at areas of minimal strain of the electronic device in the curved conformation of the bistable structure.

2. The electronic device of claim 1, wherein the spatially inhomogeneous property, the at least one stretchable interconnect, and the one or more encapsulating layers position a spatially varying neutral mechanical surface that is coincident with or proximate to the functional layer.

3. The electronic device of claim 1, wherein the one or more encapsulating layers have a thickness that varies selectively in a lateral direction.

4. The electronic device of claim 1, wherein the band further comprises a polymer, a semiconductor material, a ceramic, a metal, a fabric, a vinyl material, leather, latex, spandex, or paper.

5. The electronic device of claim 1, wherein the at least one stretchable interconnect comprises a pop-up interconnect, a curved interconnect, a serpentine interconnect, a wavy interconnect, a meander-shaped interconnect, a zig-zag interconnect, a boustrophedonic interconnect, a rippled interconnect, a buckled interconnect, or a helical interconnect.

6. The electronic device of claim 5, wherein the at least one stretchable interconnect comprises an electrically conductive stretchable interconnect or an electrically non-conductive stretchable interconnect.

7. The electronic device of claim 1, wherein the at least one functional layer comprises an optical device, a mechanical device, a microelectromechanical device, a thermal device, a chemical sensor, an accelerometer, a flow rate sensor, or any combination thereof.

8. The electronic device of claim 1, wherein one or more of the at least one device island comprises a device component selected from the group consisting of a photodiode, a light-emitting diode, a thin-film transistor, a memory, a electrocardiogram electrode, an electromyogram electrode, an integrated circuit, a contact pad, a circuit element, a control element, a microprocessor, a transducer, a biological sensor, a chemical sensor, a temperature sensor, a light sensor, an electromagnetic radiation sensor, a solar cell, a photovoltaic array, a piezoelectric sensor, an environmental sensor, or any combination thereof.

9. The electronic device of claim 1, wherein the functional layer comprises:
at least one light-emitting device; and
at least one sensor component;
wherein the at least one sensor component measures at least one parameter indicative of at least one of a physiological measure of a subject and an environmental condition; and
wherein a visual appearance of the at least one light-emitting device changes based on a magnitude of the at least one parameter.

10. The electronic device of claim 9, wherein the physiological measure is at least one of a skin temperature, a body temperature, a heart rate, a hydration state, a quantify of sweat, a blood pressure, a cardiac electricity, a muscle electricity, a stomach electricity, a skin electricity, a nerve electricity, UV exposure, and a hormone level.

11. The electronic device of claim 9, wherein the physiological measure is a quantity of at least one of a drug, a pharmaceutical, or a biologic, in a portion of a tissue of the subject, sweat from the subject, and/or body fluid from the subject.

12. The electronic device of claim 9, wherein the environmental condition is at least one of a humidity, an atmospheric temperature, an amount of chlorofluorocarbon, an amount of volatile organic compound, a UV level, and an atmospheric pressure.

13. The electronic device of claim 1, wherein the bistable structure comprises a tape spring steel or a carbon spring steel.

14. The electronic device of claim 1, further comprising at least one triggering mechanism, wherein the at least one triggering mechanism is coupled to the band such that at least one device component of the at least one device island is activated when the bistable structure is in the extended conformation and such that the at least one device component of the at least one device island is deactivated when the bistable structure is in the curved conformation.

15. The electronic device of claim 14, wherein the at least one device component is an accelerometer, a photodiode, a light-emitting diode, a microprocessor, a transducer, a biological sensor, a chemical sensor, a temperature sensor, a light sensor, an electromagnetic radiation sensor, a piezoelectric sensor, an environmental sensor, or any combination thereof.

16. The electronic device of claim 14, wherein the at least one triggering mechanism comprises at least one of contact pads, a mechanical snap switch, a dome switch, and magnets.

17. The electronic device of claim 1, further comprising at least one wireless component that has a linear configuration when the bistable structure is in the extended conformation and has a charging coil configuration when the bistable structure is in the curved conformation.

18. An electronic device, comprising:
a band comprising a plurality of bistable structures, wherein each bistable structure of the plurality of bistable structures has an extended conformation and a curved conformation, and wherein the band has a first surface;
an isolation layer disposed over a portion of the first surface,
wherein at least a portion of the isolation layer is disposed over at least one bistable structure of the plurality of bistable structures;
a functional layer disposed over the first surface, the functional layer comprising:
at least one device island; and
at least one stretchable interconnect coupled to the at least one device island at a junction region;
wherein at least a portion of the device island and the junction region is in physical communication with the isolation layer; and
wherein at least a portion of the stretchable interconnect is not in physical communication with the isolation layer;
one or more neutral mechanical surface adjusting layers disposed over at least a portion of the functional layer; and
one or more encapsulating layers disposed over be one or more neutral mechanical surface adjusting layers;
wherein the one or more neutral mechanical surface adjusting layers have a property that is spatially inhomogeneous relative to a location in the electronic device; and
wherein the at least one device island and at least one stretchable interconnect are disposed about the band such that the at least one device island and the junction region are disposed at areas of minimal strain of the electronic device in the curved conformation of at least one of the plurality of bistable structures.

19. The electronic device of claim 18, wherein the spatially inhomogeneous property, the at least one stretchable interconnect, and the one or more encapsulating layers position a spatially varying neutral mechanical surface that is coincident with or proximate to the functional layer.

20. The electronic device of claim 18, wherein the band further comprises a polymer, a semiconductor material, a ceramic, a metal, a fabric, a vinyl material, leather, latex, spandex, or paper.

21. The electronic device of claim 18, wherein the at least one stretchable interconnect comprises a pop-up interconnect, a curved interconnect, a serpentine interconnect, a wavy interconnect, a meander-shaped interconnect, a zig-zag interconnect, a boustrophedonic interconnect, a rippled interconnect, a buckled interconnect, or a helical interconnect.

22. The electronic device of claim 21, wherein the at least one stretchable interconnect comprises an electrically conductive stretchable interconnect or an electrically non-conductive stretchable interconnect.

23. The electronic device of claim 18, wherein the at least one functional layer comprises an optical device, a mechanical device, a microelectromechanical device, a thermal device, a chemical sensor, an accelerometer, a flow rate sensor, or any combination thereof.

24. The electronic device of claim 18, wherein one or more of the at least one device island comprises a device component selected from the group consisting of a photodiode, a light-emitting diode, a thin-film transistor, a memory, a electrocardiogram electrode, an electromyogram electrode, an integrated circuit, a contact pad, a circuit element, a control element, a microprocessor, a transducer, a biological sensor, a chemical sensor, a temperature sensor, a light sensor, an electromagnetic radiation sensor, a solar cell, a photovoltaic array, a piezoelectric sensor, an environmental sensor, or any combination thereof.

25. The electronic device of claim 18, wherein the functional layer comprises:
at least one light-emitting device; and
at least one sensor component;
wherein the at least one sensor component measures at least one parameter indicative of at least one of a physiological measure of a subject and an environmental condition; and
wherein a visual appearance of the at least one light-emitting device changes based on a magnitude of the at least one parameter.

26. The electronic device of claim 25, wherein the physiological measure is at least one of a skin temperature, a body temperature, a heart rate, a hydration state, a quantify of sweat, a blood pressure, a cardiac electricity, a muscle electricity, a stomach electricity, a skin electricity, a nerve electricity, UV exposure, and a hormone level.

27. The electronic device of claim 25, wherein the physiological measure is a quantity of at least one of a drug, a pharmaceutical, or a biologic, in a portion of a tissue of the subject, sweat from the subject, and/or body fluid from the subject.

28. The electronic device of claim 25, wherein the environmental condition is at least one of a humidity, an atmospheric temperature, an amount of chlorofluorocarbon, an amount of volatile organic compound, a UV level, and an atmospheric pressure.

29. The electronic device of claim 18, wherein at least one bistable structure of the plurality of bistable structures comprises a tape spring steel or a carbon spring steel.

30. The electronic device of claim 18, further comprising at least one wireless component that has a linear configuration when at least one bistable structure of the plurality of bistable structures is in the extended conformation and has a charging coil configuration when at least one bistable structure of the plurality of bistable structures is in the curved conformation.
